(19) United States
(12) Patent Application Publication
(10) Pub. No.: US 2026/0206439 A1
(43) Pub. Date: Jul. 16, 2026

(54) DISPLAY PANEL AND ELECTRONIC DEVICE INCLUDING THE SAME

(71) Applicant: Samsung Display Co., Ltd., Yongin-si (KR)

(72) Inventors: Soohong Cheon, Yongin-si (KR); Kyeuk Lee, Yongin-si (KR); Seongyoung Lee, Yongin-si (KR)

(21) Appl. No.: 19/386,054

(22) Filed: Nov. 11, 2025

(30) Foreign Application Priority Data
Nov. 12, 2024 (KR) 10-2024-0160484

(51) Int. Cl. H10K 59/131; H10K 59/124; H10K 59/80

(52) U.S. Cl. CPC H10K 59/131; H10K 59/124; H10K 59/873

(57) ABSTRACT

A display panel includes a substrate including a display area and a non-display area, a driving voltage input unit in the non-display area, and including a horizontal driving voltage input unit extending along a first direction, and a vertical driving voltage input unit extending along a second direction crossing the first direction, and including a first vertical driving voltage input unit having a side surface extending along the second direction, a second vertical driving voltage input unit having a side surface extending along a diagonal direction between the first and second directions, and a third vertical driving voltage input unit having a side surface extending along the second direction, the first, second, and third vertical driving voltage input units being sequentially arranged along the second direction, and a common voltage input unit in the non-display area, and spaced apart from the driving voltage input unit.

### CROSS-REFERENCE TO RELATED APPLICATION

The present application claims priority to, and the benefit of, Korean Patent Application No. 10-2024-0160484, filed on Nov. 12, 2024, in the Korean Intellectual Property Office, the entire disclosure of which is incorporated herein by reference.

### BACKGROUND

### 1. Field

The present disclosure relates to a display panel and an electronic device including the same.

### 2. Description of the Related Art

In general, as display panels that visually display electrical signals have been developed, various display panels with excellent characteristics, such as a thin design, reduced weight, and low power consumption, and electronic devices including such display panels, have been introduced. Display panels may provide images by using light-emitting diodes. Display panels and electronic devices including the same have been used for various purposes, and various designs have been attempted to improve the quality of display panels and electronic devices including the same.

### SUMMARY

Embodiments of the present disclosure are directed to providing a display panel for displaying a high-quality image and an electronic device including the display panel. However, the embodiments are examples and do not limit the scope of the present disclosure.

Additional aspects will be set forth in part in the description that follows and, in part, will be apparent from the description, or may be learned by practice of the presented embodiments of the disclosure.

According to one or more embodiments of the present disclosure, a display panel includes a substrate including a display area, and a non-display area outside the display area, a driving voltage input unit in the non-display area, and including a horizontal driving voltage input unit extending along a first direction, and a vertical driving voltage input unit extending along a second direction crossing the first direction, and including a first vertical driving voltage input unit having a side surface extending along the second direction, a second vertical driving voltage input unit having a side surface extending along a diagonal direction between the first direction and the second direction, and a third vertical driving voltage input unit having a side surface extending along the second direction, the first vertical driving voltage input unit, the second vertical driving voltage input unit, and third vertical driving voltage input unit being sequentially arranged along the second direction, and a common voltage input unit in the non-display area, and spaced apart from the driving voltage input unit.

The horizontal driving voltage input unit, the first vertical driving voltage input unit, the second vertical driving voltage input unit, and the third vertical driving voltage input unit may be integral.

The second vertical driving voltage input unit may have a trapezoidal shape in a plan view.

The first vertical driving voltage input unit may have a first width along the first direction, wherein the third vertical driving voltage input unit has a second width along the first direction that is different from the first width, wherein one side of the second vertical driving voltage input unit adjacent the first vertical driving voltage input unit has the first width, and wherein another side of the second vertical driving voltage input unit adjacent the third vertical driving voltage input unit has the second width.

The common voltage input unit may be provided as a plurality of common voltage input units, wherein the vertical driving voltage input unit is between adjacent ones of the common voltage input units adjacent along the first direction.

The non-display area may include a separation area where the driving voltage input unit and the common voltage input unit are spaced apart from each other, the separation area exposing a top surface of an insulating layer that is lower than the driving voltage input unit and the common voltage input unit, and having a portion extending in the diagonal direction.

The non-display area may include a separation area where the driving voltage input unit and the common voltage input unit are spaced apart from each other, the separation area exposing a top surface of an insulating layer that is lower than the driving voltage input unit and the common voltage input unit, and including a first separation area extending along the first direction between the horizontal driving voltage input unit and the common voltage input unit, a second separation area extending along the second direction between the first vertical driving voltage input unit and the common voltage input unit, a third separation area extending along the diagonal direction between the second vertical driving voltage input unit and the common voltage input unit, and a fourth separation area extending along the second direction between the third vertical driving voltage input unit and the common voltage input unit.

The display panel may further include dams in the non-display area and above the driving voltage input unit and the common voltage input unit, wherein the dams are arranged to surround the display area, and wherein the dams overlap the vertical driving voltage input unit and the common voltage input unit.

The display panel may further include dams in the non-display area above the driving voltage input unit and the common voltage input unit and surrounding the display area in plan view, wherein a closest one of the dams to the display area overlaps the second vertical driving voltage input unit.

The display panel may further include dams in the non-display area above the driving voltage input unit and the common voltage input unit, and surrounding the display area in plan view, insulating layers above the driving voltage input unit and the common voltage input unit, and a light-emitting diode in the display area, and electrically connected to a contact area of the common voltage input unit at which a portion of the insulating layers is removed to expose a top surface of the common voltage input unit, the contact area being closer to the display area than the dams are.

The display panel may further include dams in the non-display area above the driving voltage input unit and the common voltage input unit, and surrounding the display area in plan view, a light-emitting diode in the display area, and an encapsulation layer covering the light-emitting diode, and including a first inorganic encapsulation layer, an organic encapsulation layer above the first inorganic encapsulation layer, and a second inorganic encapsulation layer above the organic encapsulation layer and directly contacting the first inorganic encapsulation layer above the dams.

According to one or more other embodiments of the present disclosure, a display panel includes a substrate including a display area, and a non-display area outside the display area, a driving voltage input unit in the non-display area, and including a horizontal driving voltage input unit extending along a first direction, and a vertical driving voltage input unit extending along a second direction crossing the first direction, and a common voltage input unit in the non-display area and spaced apart from the driving voltage input unit, wherein the non-display area includes a separation area where the driving voltage input unit and the common voltage input unit are spaced apart from each other, and having a portion in a diagonal direction between the first direction and the second direction.

The separation area may expose a top surface of an insulating layer that is lower than the driving voltage input unit and the common voltage input unit.

The common voltage input unit may be in the non-display area, and is spaced apart from the driving voltage input unit, wherein the vertical driving voltage input unit includes a first vertical driving voltage input unit having a side surface facing the common voltage input unit and extending along the second direction, a second vertical driving voltage input unit having a trapezoidal shape in a plan view, and having a side surface facing the common voltage input unit and extending along the diagonal direction, and a third vertical driving voltage input unit having a side surface facing the common voltage input unit and extending along the second direction, the first vertical driving voltage input unit, the second vertical driving voltage input unit, and the third vertical driving voltage input unit being sequentially arranged along the second direction.

The display panel may further include dams in the non-display area above the driving voltage input unit and the common voltage input unit, and surrounding the display area in plan view, wherein a closest one of the dams to the display area overlaps a portion of the separation area extending in the diagonal direction.

The display panel may further include dams in the non-display area above the driving voltage input unit and the common voltage input unit, and surrounding the display area in plan view, and a light-emitting diode in the display area, and electrically connected to a contact area of the common voltage input unit that is closer to the display area in plan view than the dams are.

According to one or more other embodiments of the present disclosure, an electronic device includes a display panel, and a lower cover as an exterior, and defining an opening exposing a part of the display panel, wherein the display panel includes a substrate including a display area, and a non-display area outside the display area, a driving voltage input unit in the non-display area, and including a horizontal driving voltage input unit extending along a first direction, and a vertical driving voltage input unit extending along a second direction crossing the first direction, and including a first vertical driving voltage input unit having a side surface extending along the second direction, a second vertical driving voltage input unit having a side surface extending along a diagonal direction between the first direction and the second direction, and a third vertical driving voltage input unit having a side surface extending along the second direction, the first vertical driving voltage input unit, the second vertical driving voltage input unit, and third vertical driving voltage input unit being sequentially arranged along the second direction, and a common voltage input unit in the non-display area and spaced apart from the driving voltage input unit.

The non-display area may include a separation area where the driving voltage input unit and the common voltage input unit are spaced apart from each other that exposes a top surface of an insulating layer that is lower the driving voltage input unit and the common voltage input unit, and that has a portion extending in the diagonal direction.

The electronic device may further include dams in the non-display area above the driving voltage input unit and the common voltage input unit, and surrounding the display area in plan view, wherein a closest one of the dams to the display area overlaps the second vertical driving voltage input unit in a plan view.

The electronic device may further include dams in the non-display area above the driving voltage input unit and the common voltage input unit, and surrounding the display area in plan view, and a light-emitting diode in the display area, and electrically connected to a contact area of the common voltage input unit that is closer to the display area than the dams are.

### BRIEF DESCRIPTION OF THE DRAWINGS

The above and other aspects of certain embodiments of the disclosure will be more apparent from the following description taken in conjunction with the accompanying drawings, in which:

FIG. 1A is a perspective view schematically illustrating an electronic device, according to one or more embodiments of the present disclosure;

FIG. 1B is a block diagram schematically illustrating an electronic device, according to one or more embodiments of the present disclosure;

FIG. 2 is a perspective view schematically illustrating a display panel, according to one or more embodiments of the present disclosure;

FIG. 3 is a cross-sectional view schematically illustrating a display panel, according to one or more embodiments of the present disclosure;

FIG. 4 is an equivalent circuit diagram illustrating one pixel included in a display panel, according to one or more embodiments of the present disclosure;

FIG. 5 is a plan view schematically illustrating a display panel, according to one or more embodiments of the present disclosure;

FIG. 6 is a cross-sectional view taken along the line A-A′ of the display panel of FIG. 5;

FIG. 7 is a cross-sectional view taken along the line B-B′ of the display panel of FIG. 5;

FIGS. 8A and 8B are plan views schematically illustrating a portion of a display panel, according to one or more embodiments of the present disclosure;

FIG. 8C is an enlarged plan view schematically illustrating a portion D of the display panel of FIG. 8B; and

FIG. 9 is a cross-sectional view taken along the line E-E′ of the display panel of FIG. 8B.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer, or section described below could be termed a second element, component, region, layer, or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same.” In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

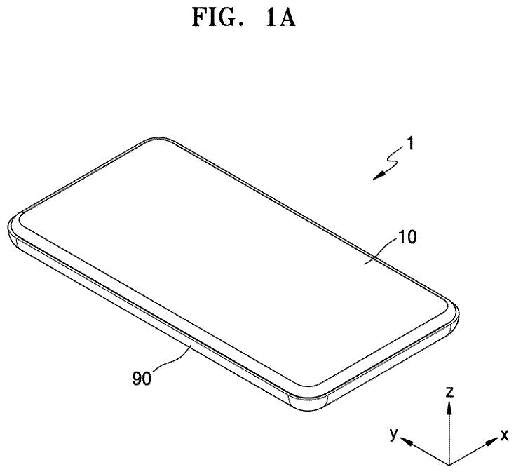

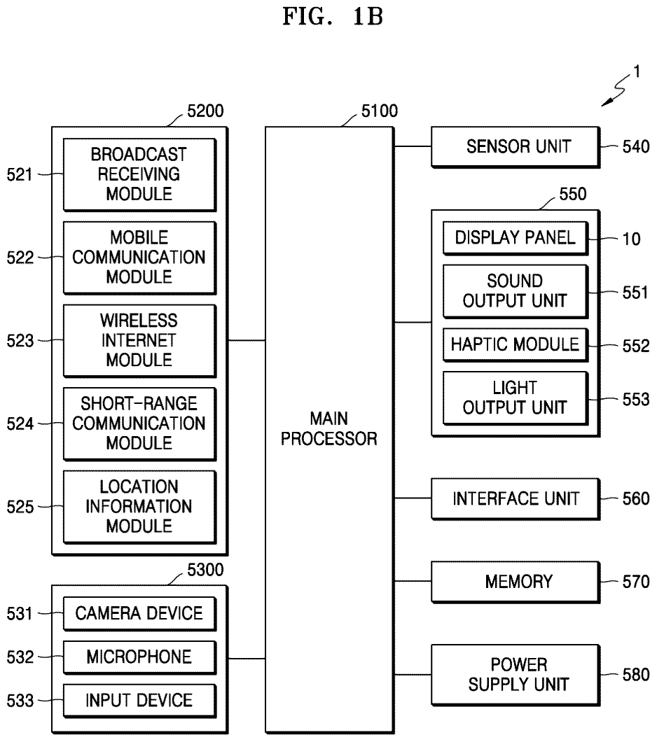

FIG. 1A is a perspective view schematically illustrating an electronic device 1, according to one or more embodiments of the present disclosure, and FIG. 1B is a block diagram schematically illustrating the electronic device 1, according to one or more embodiments of the present disclosure.

Referring to FIGS. 1A and 1B, the electronic device 1 according to one or more embodiments of the present disclosure is a device for displaying a moving image or a still image, and may be used as a display screen for not only a portable electronic device, such as a mobile phone, a smartphone, a tablet personal (PC) computer, a mobile communication terminal, an electronic organizer, an electronic book, a portable multimedia player (PMP), a navigation device, or an ultra-mobile PC (UMPC), but also any of various products, such as a television, a laptop computer, a monitor, an advertisement board, or an Internet of things (IoT) product. The electronic device 1 according to one or more embodiments may be used in a wearable device, such as a smart watch, a watch phone, a glasses-type display, or a head-mounted display (HMD). Also, the electronic device 1 according to one or more embodiments may be used as a center information display (CID) located on an instrument panel, a center fascia, or a dashboard of a vehicle, a room mirror display replacing a side-view mirror of a vehicle, or a display located on the back of a front seat for entertainment of a rear seat passenger of a vehicle.

The electronic device 1 according to one or more embodiments is a smartphone in FIG. 1A. The electronic device 1 may include a display panel 10 and a lower cover 90 located under the display panel 10. The electronic device 1 may include a cover window covering a top surface of the display panel 10.

The lower cover 90 may form an exterior of the electronic device 1, and an opening through which a part of the display panel 10 is exposed may be formed in a front surface of the lower cover 90. The lower cover 90 has a shape whose surface corresponding to the display panel 10 is open, and may be assembled with the display panel 10. The lower cover 90 forms a lower exterior of the electronic device 1, and a display circuit board, a component, a main circuit board, a battery, a driver, etc. may be located between the display panel 10 and the lower cover 90. The lower cover 90 may include plastic, metal, or both plastic and metal.

The electronic device 1 may include a main processor 5100, a wireless communication unit 5200, an input unit 5300, a sensor unit 540, an output unit 550, an interface unit 560, a memory 570, and/or a power supply unit 580.

The main processor 5100 may control all functions of the electronic device 1. For example, the main processor 5100 may output digital video data to a data driver through the display circuit board so that the display panel 10 displays an image. The main processor 5100 may receive detection data from a touch sensor driver. The main processor 5100 may determine whether a user touches according to the detection data, and may perform an operation corresponding to the user's direct touch or proximity touch. The main processor 5100 may be an application processor, a central processing unit, or a system chip formed as an integrated circuit (IC).

A camera device 531 processes an image frame, such as a still image or a moving image obtained by an image sensor in a camera mode, and outputs the image frame to the main processor 5100. The camera device 531 may include at least one of a camera sensor (e.g., CCD or CMOS), a photo sensor (or image sensor), or a laser sensor. The camera device 531 may be connected to the image sensor and may process an image input through the image sensor.

The wireless communication unit 5200 may include at least one of a broadcast receiving module 521, a mobile communication module 522, a wireless Internet module 523, a short-range communication module 524, or a location information module 525.

The broadcast receiving module 521 receives a broadcast signal and/or broadcast-related information from an external broadcast management server through a broadcast channel. Examples of the broadcast channel may include a satellite channel and a terrestrial channel.

The mobile communication module 522 transmits and receives a wireless signal to and from at least one of a base station, an external terminal, or a server in a mobile communication network established according to technical standards or communication methods for mobile communication (e.g., global system for mobile communication (GSM), code division multi-access (CDMA), code division multi-access 2000 (CDMA2000), enhanced voice-data optimized or enhanced voice-data only (EV-DO), wideband CDMA (WCDMA), high speed downlink packet access (HSDPA), high speed uplink packet access (HSUPA), long term evolution (LTE), or long term evolution-advanced (LTE-A)). The wireless signal may include various types of data according to transmission and reception of a voice call signal, a video call signal, or a text/multimedia message.

The wireless Internet module 523 refers to a module for wireless Internet access. The wireless Internet module 523 may be configured to transmit and receive a wireless signal in a communication network according to wireless Internet technology. Examples of the wireless Internet technology include wireless LAN (WLAN), wireless-fidelity (Wi-Fi®) (Wi-Fi® being a registered trademark of the non-profit Wi-Fi Alliance), Wi-Fi® direct, and digital living network alliance (DLNA).

The short-range communication module 524 for short-range communication may support short-range communication by using at least one of Bluetooth™ (Bluetooth™ being a registered trademark of Bluetooth Sig, Inc., Kirkland, WA), radio frequency identification (RFID), infrared data association (IrDA), ultra-wideband (UWB), Zigbee® (Zigbee® being a registered trademark of CONNECTIVITY STANDARDS ALLIANCE, Davis, CA), near field communication (NFC), wireless-fidelity (Wi-Fi®), Wi-Fi® direct, or wireless universal serial bus (USB) technology. The short-range communication module 524 may support wireless communication between the electronic device 1 and a wireless communication system, between the electronic device 1 and another electronic device, or between the electronic device 1 and a network in which another electronic device (or an external server) is located through a wireless area network. The wireless area network may be a wireless personal area network. The other electronic device may be a wearable device that may exchange data (or interoperate) with the electronic device 1.

The location information module 525 for obtaining a location (or a current location) of the electronic device 1 may include a global positioning system (GPS) module or a wireless fidelity (Wi-Fi®) module.

The input unit 5300 may include an image input unit, such as the camera device 531 for inputting an image signal, a sound input unit, such as a microphone 532 for inputting a sound signal, and an input device 533 for receiving information from the user.

The camera device 531 processes an image frame, such as a still image or a moving image obtained by the image sensor in a video call mode or a photographing mode. The processed image frame may be displayed on the display panel 10 or may be stored in the memory 570.

The microphone 532 processes an external sound signal into electrical voice data. The processed voice data may be used in various ways according to a function being performed (or an application being executed) in the electronic device 1.

The main processor 5100 may control an operation of the electronic device 1 in response to information input through the input device 533. The input device 533 may include a mechanical input means or a touch input means, such as a button, a dome switch, a jog wheel, or a jog switch located on a rear surface or a side surface of the electronic device 1. The touch input means may include a touchscreen layer of the display panel 10.

The sensor unit 540 may include one or more sensors that sense at least one of information in the electronic device 1, environment information surrounding the electronic device 1, or user information, and generates a corresponding sensing signal. The main processor 5100 may control the driving or operation of the electronic device 1 or may perform data processing, a function, or an operation related to an application installed in the electronic device 1. The sensor unit 540 may include at least one of a proximity sensor, an illumination sensor, an acceleration sensor, a magnetic sensor, a G-sensor, a gyroscope sensor, a motion sensor, an RGB sensor, an infrared (IR) sensor, a finger scan sensor, an ultrasonic sensor, an optical sensor, a battery gauge, an environmental sensor (e.g., a barometer, a hygrometer, a thermometer, a radiation detection sensor, a heat sensor, or a gas sensor), or a chemical sensor (e.g., an electronic nose, a healthcare sensor, or a biometric sensor).

The output unit 550 for generating an output related to visual, auditory, or tactile sense may include at least one of the display panel 10, a sound output unit 551, a haptic module 552, or a light output unit 553.

The display panel 10 displays (outputs) information processed by the electronic device 1. For example, the display panel 10 may display execution screen information of an application driven by the electronic device 1 or user interface (UI) or graphical user interface (GUI) information according to the execution screen information. The display panel 10 may include a display layer for displaying an image and a touchscreen layer for detecting a touch input of the user. Accordingly, the display panel 10 may function as one of input devices 533 that provide an input interface between the electronic device 1 and the user, and at the same time, may also function as one of output units 550 that provide an output interface between the electronic device 1 and the user.

The sound output unit 551 may output sound data received from the wireless communication unit 5200 or stored in the memory 570, in a signal reception mode, a call mode or a recording mode, a voice recognition mode, or a broadcast reception mode. The sound output unit 551 may output a sound signal related to a function (e.g., a call signal reception sound or a message reception sound) performed in the electronic device 1. The sound output unit 551 may include a receiver and a speaker. At least one of the receiver or the speaker may be a sound generating device that is attached to the bottom of the display panel 10 and outputs sound by vibrating the display panel 10. The sound generating device may be a piezoelectric element or a piezoelectric actuator that contracts or expands according to an electrical signal, or an exciter that generates a magnetic force by using a voice coil and vibrates the display panel 10.

The haptic module 552 generates various tactile effects that the user may feel. The haptic module 552 may provide vibration to the user as a tactile effect. The haptic module 552 may not only transfer a tactile effect through direct contact, but may also allow the user to feel a tactile effect through a muscle sense, such as a finger or arm of the user.

The light output unit 553 outputs a signal for notifying the occurrence of an event by using light of a light source. Examples of events occurring in the electronic device 1 may include message reception, call signal reception, missed call, alarm, schedule notification, email reception, and or information reception through an application. A signal output from the light output unit 553 is implemented as the electronic device 1 emits light of a single color or multiple colors from a front surface or a rear surface. The signal output may be terminated when the electronic device 1 detects that the user has confirmed the event.

The interface unit 560 functions as a passage with various types of external devices connected to the electronic device 1. The interface unit 560 may include at least one of a wired/wireless headset port, an external charger port, a wired/wireless data port, a memory card port, a port for connecting a device including an identification module, an audio input/output (I/O) port, a video I/O port, or an earphone port. When an external device is connected to the interface unit 560, the electronic device 1 may perform appropriate control related to the connected external device.

The memory 570 stores data that supports various functions of the electronic device 1. The memory 570 may store a plurality of applications (application programs) running on the electronic device 1 and pieces of data and instructions for an operation of the electronic device 1. At least some of the plurality of applications may be downloaded from an external server through wireless communication. The memory 570 may store an application for an operation of the main processor 5100, and may temporarily store input/output data, for example, a phone book, a message, a still image, and a moving image. Also, the memory 570 may store haptic data for vibration of various patterns provided to the haptic module 552 and sound data related to various sounds provided to the sound output unit 551. The memory 570 may include at least one type of storage medium among a flash memory type, a hard disk type, a solid state disk (SSD) type, a silicon disk drive (SDD) type, a multimedia card micro type, a card type memory (e.g., SD or XD memory), a random-access memory (RAM), a static random-access memory (SRAM), a read-only memory (ROM), an electrically erasable programmable read-only memory (EEPROM), a programmable read-only memory (PROM), a magnetic memory, a magnetic disk, or an optical disk.

The power supply unit 580 receives external power or internal power and supplies the power to each component included in the electronic device 1, under the control of the main processor 5100. The power supply unit 580 may include a battery. Also, the power supply unit 580 includes a connection port, and the connection port may be an example of the interface unit 560 to which an external charger for supplying power is electrically connected to charge the battery. Alternatively, the power supply unit 580 may charge the battery in a wireless manner without using the connection port.

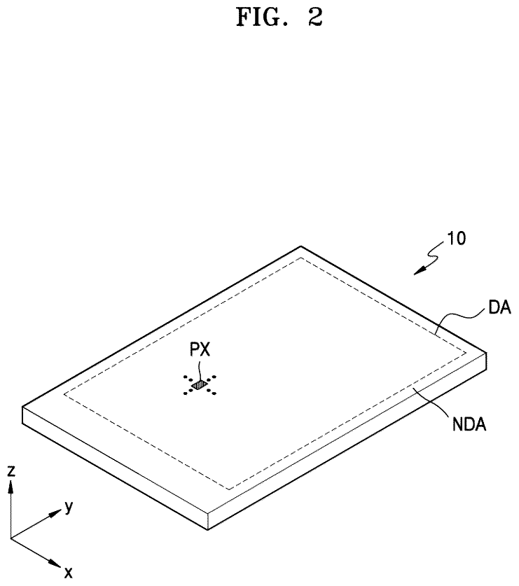

FIG. 2 is a perspective view schematically illustrating a display panel, according to one or more embodiments of the present disclosure.

Referring to FIG. 2, the display panel 10 may include a display area DA where an image is displayed, and a non-display area NDA where an image is not displayed. The display panel 10 may provide an image to the outside by using light emitted from the display area DA.

Although the display area DA of the display panel 10 has a quadrangular shape in FIG. 2, in one or more other embodiments, the display area DA may have a circular shape, an elliptical shape, or a polygonal shape, such as a triangular shape or a pentagonal shape. Also, although the display panel 10 of FIG. 2 is a flat display panel, the display panel 10 may be implemented as any of various types of display panels, such as a flexible, foldable, or rollable display panel.

In one or more embodiments, the display panel 10 may be an organic light-emitting display panel. In one or more other embodiments, the display panel 10 may be an inorganic light-emitting display panel or a quantum-dot light-emitting display panel. For example, an emission layer of a display element included in the display panel may include an organic material, may include an inorganic material, may include quantum dots, may include an organic material and quantum dots, may include an inorganic material and quantum dots, or may include an organic material, an inorganic material, and quantum dots. For convenience of explanation, the following will be described assuming that the display panel 10 is an organic light-emitting display panel.

A plurality of pixels PX may be located in the display area DA. In the specification, each pixel PX refers to a sub-pixel that emits light of a different color, and each pixel PX may be one of, for example, a red sub-pixel, a green sub-pixel, and a blue sub-pixel.

In the non-display area NDA where the pixel PX is not located, a power supply wiring for driving the pixel PX may be located. Also, a terminal portion to which a printed circuit board including a driving circuit unit or a driver IC is connected may be located in the non-display area NDA. Alternatively, the driving circuit unit may be located in the non-display area NDA.

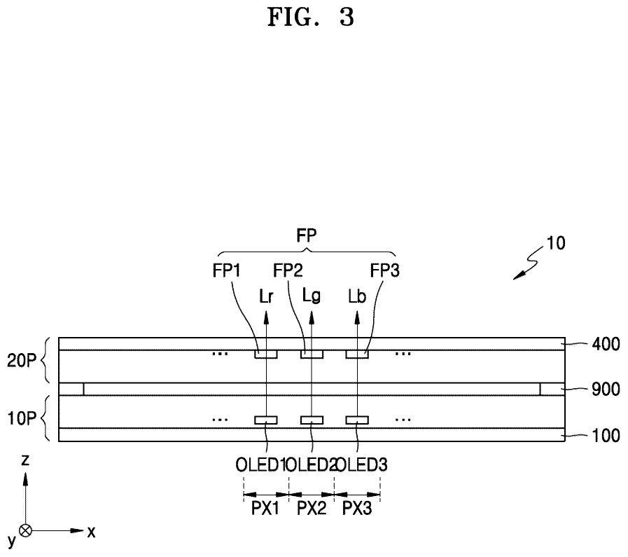

FIG. 3 is a cross-sectional view schematically illustrating a display panel, according to one or more embodiments of the present disclosure.

Referring to FIG. 3, the display panel 10 may include a first pixel PX1, a second pixel PX2, and a third pixel PX3. The first pixel PX1, the second pixel PX2, and the third pixel PX3 may be pixels emitting light of different respective colors. For example, the first pixel PX1 may emit red light Lr, the second pixel PX2 may emit green light Lg, and the third pixel PX3 may emit blue light Lb. In one or more embodiments, the display panel 10 may include a lower panel 10P and an upper panel 20P. The lower panel 10P may include a first substrate 100 and a light-emitting element. The light-emitting element may be, for example, an organic light-emitting diode. In one or more embodiments, each of the first pixel PX1, the second pixel PX2, and the third pixel PX3 may include an organic light-emitting diode. For example, the first pixel PX1 may include a first organic light-emitting diode OLED1. The second pixel PX2 may include a second organic light-emitting diode OLED2. The third pixel PX3 may include a third organic light-emitting diode OLED3.

In one or more embodiments, the first organic light-emitting diode OLED1, the second organic light-emitting diode OLED2, and the third organic light-emitting diode OLED3 may emit blue light. In one or more other embodiments, the first organic light-emitting diode OLED1, the second organic light-emitting diode OLED2, and the third organic light-emitting diode OLED3 may respectively emit the red light Lr, the green light Lg, and the blue light Lb.

The upper panel 20P may include a second substrate 400 and a filter unit FP. In one or more embodiments, the filter unit FP may include a first filter unit FP1, a second filter unit FP2, and a third filter unit FP3. Light emitted by the first organic light-emitting diode OLED1 may be emitted as the red light Lr through the first filter unit FP1. Light emitted by the second organic light-emitting diode OLED2 may be emitted as the green light Lg through the second filter unit FP2. Light emitted by the third organic light-emitting diode OLED3 may be emitted as the blue light Lb through the third filter unit FP3.

In one or more embodiments, the filter unit FP may include a light conversion unit and a color filter layer. In one or more embodiments, functional layers included in the light conversion unit may include a first quantum dot layer, a second quantum dot layer, and a transmissive layer. In one or more embodiments, the color filter layer include a first color filter, a second color filter, and a third color filter. The first filter unit FP1 may include the first quantum dot layer and the first color filter. The second filter unit FP2 may include the second quantum dot layer and the second color filter. The third filter unit FP3 may include the transmissive layer and the third color filter.

The filter unit FP may be located directly on the second substrate 400. In this case, when ‘located directly on the second substrate 400’ may mean that the upper panel 20P is manufactured by directly forming the first color filter, the second color filter, and the third color filter on the second substrate 400. That is, the filter unit FP may be located on a bottom surface of the second substrate 400. Next, the upper panel 20P may be adhered to the lower panel 10P so that the first filter unit FP1, the second filter unit FP2, and the third filter unit FP3 respectively face the first organic light-emitting diode OLED1, the second organic light-emitting diode OLED2, and the third organic light-emitting diode OLED3.

The lower panel 10P and the upper panel 20P may be connected to each other through a sealing member 900. In this case, the sealing member 900 may surround the display area DA of the lower panel 10P (e.g., in plan view). For example, the sealing member 900 may be located outside the display area DA in a plan view and may form a closed-loop. In this case, the sealing member 900 and the upper panel 20P may be completely isolate the display area DA from the outside. The sealing member 900 may be formed of a sealant or a frit.

In one or more embodiments, a filler may be located between the lower panel 10P and the upper panel 20P.

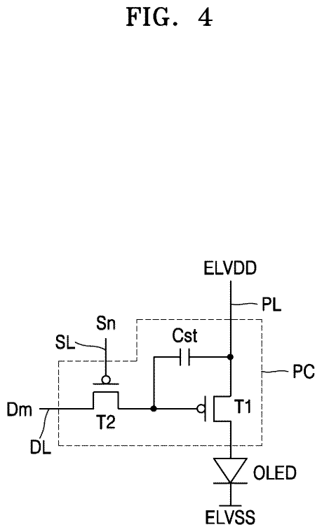

FIG. 4 is an equivalent circuit diagram illustrating one pixel included in a display apparatus, according to one or more embodiments of the present disclosure.

Referring to FIG. 4, each pixel may be implemented by a pixel circuit PC connected to the scan line SL and the data line DL, and an organic light-emitting diode OLED connected to the pixel circuit PC. The pixel circuit PC may include a driving thin-film transistor T1, a switching thin-film transistor T2, and a storage capacitor Cst. The switching thin-film transistor T2 may be connected to the scan line SL and the data line DL, and may transmit a data signal Dm input through the data line DL to the driving thin-film transistor T1 according to a scan signal Sn input through the scan line SL.

The storage capacitor Cst may be connected to the switching thin-film transistor T2 and a driving voltage line PL, and may store a voltage corresponding to a difference between a voltage received from the switching thin-film transistor T2 and a first power supply voltage ELVDD (or a driving voltage) supplied to the driving voltage line PL.

The driving thin-film transistor T1 may be connected to the driving voltage line PL and the storage capacitor Cst, and may control driving current flowing from the driving voltage line PL to the organic light-emitting diode OLED in response to a value of the voltage stored in the storage capacitor Cst. The organic light-emitting diode OLED may emit light having a certain luminance due to the driving current.

Although the pixel circuit PC includes two thin-film transistors and one storage capacitor in FIG. 4, the present disclosure is not limited thereto and the number and circuit design may be changed in various ways.

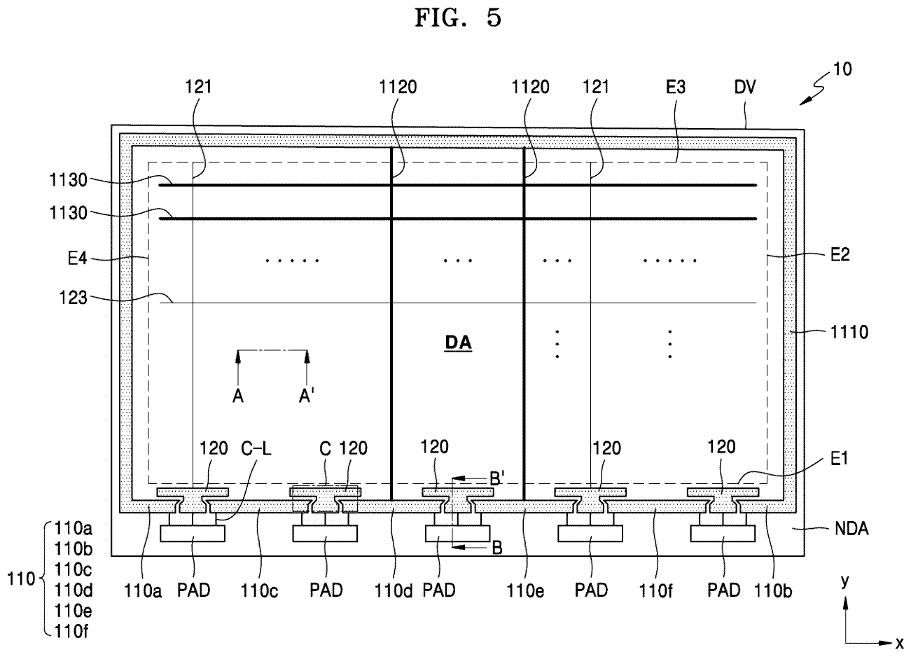

FIG. 5 is a plan view illustrating a display panel, according to one or more embodiments of the present disclosure.

As described with reference to FIG. 2, the display panel 10 may include the display area DA where a plurality of pixels are located, and the non-display area NDA outside the display area DA. The non-display area NDA is an area where an image is not provided, a driver or a voltage wiring for providing an electrical signal or power to pixel circuits may be located in the non-display area NDA, and the non-display area NDA may include a pad PAD to which an electronic device or a printed circuit board may be electrically connected.

Referring to FIG. 5, a common voltage input unit 110, a driving voltage input unit 120, and the pad PAD may be located in the non-display area NDA adjacent to a first edge E1 of the display area DA.

A plurality of common voltage input units 110 may be provided along the first edge E1 of the display area DA. In this regard, in FIG. 5, a first common voltage input unit 110a and a second common voltage input unit 110b are respectively located at both ends of the first edge E1 of the display area DA, and third to sixth common voltage input units 110c, 110d, 110e, and 110f are spaced apart from each other and arranged along the first edge E1.

The first common voltage input unit 110a and the second common voltage input unit 110b may be connected to each other by a main common voltage line 1110 extending along a second edge E2, a third edge E3, and a fourth edge E4 of the display area DA. In other words, the first common voltage input unit 110a, the second common voltage input unit 110b, and the main common voltage line 1110 may be integrally formed with each other (e.g., may be integral).

The common voltage input units 110 and the main common voltage line 1110 may be electrically connected to a counter electrode of the organic light-emitting diodes OLED (see FIG. 4). For example, the counter electrode of the organic light-emitting diodes OLED (see FIG. 4) may entirely cover the display area DA, and may extend to the non-display area NDA to directly contact the common voltage input units 110 and a part of the main common voltage line 1110.

Vertical common voltage lines 1120 and horizontal common voltage lines 1130 electrically connected to the common voltage input unit 110 and the main common voltage line 1110 may be located in the display area DA. The vertical common voltage lines 1120 may cross the display area DA in a second direction (e.g., a y direction) to electrically connect the common voltage input unit 110 to the main common voltage line 1110. The horizontal common voltage lines 1130 may extend in a first direction (e.g., an x direction) in the display area DA, and may be electrically connected to the vertical common voltage lines 1120. When the size of the display area DA is relatively large, the counter electrode of the organic light-emitting diode OLED (see FIG. 4) may cause a voltage drop in each part within the display area DA. For example, because a central portion of the display area DA may be relatively far from the common voltage input units 110 and the main common voltage line 1110, a voltage drop due to the resistance of the counter electrode itself may occur, thereby lowering display quality. The vertical common voltage line 1120 and the horizontal common voltage line 1130 crossing the display area DA may be connected to the counter electrode of the organic light-emitting diode in the display area DA to reduce or prevent the above-described voltage drop problem.

A plurality of driving voltage input units 120 may be provided along the first edge E1 of the display area DA. As shown in FIG. 5, each of the driving voltage input units 120 may be located between the common voltage input units 110 spaced apart from each other. The pads PAD may correspond to the driving voltage input units 120. For example, one driving voltage input unit 120 and the common voltage input units 110 located on both sides of the driving voltage input unit 120 may be connected to one pad PAD through a connection line C-L.

The driving voltage input unit 120 may be electrically connected to a vertical driving voltage line 121 that extends across the display area DA along the second direction (e.g., the y direction), and a horizontal driving voltage line 123 that extends across the display area DA along the first direction (e.g., the x direction). The vertical driving voltage line 121 may be the driving voltage line PL of FIG. 4. When the size of the display area DA is large, the vertical driving voltage line 121 may cause a voltage drop in each part within the display area DA. For example, because a portion of the display area DA adjacent to the third edge E3 is far from the driving voltage input unit 120, a drop voltage due to the resistance of the vertical driving voltage line 121 itself may occur. Accordingly, the horizontal driving voltage lines 123 crossing the display area DA along the first direction (e.g., the x direction) may be connected to the vertical driving voltage lines 121 to reduce or prevent the above-described voltage drop problem.

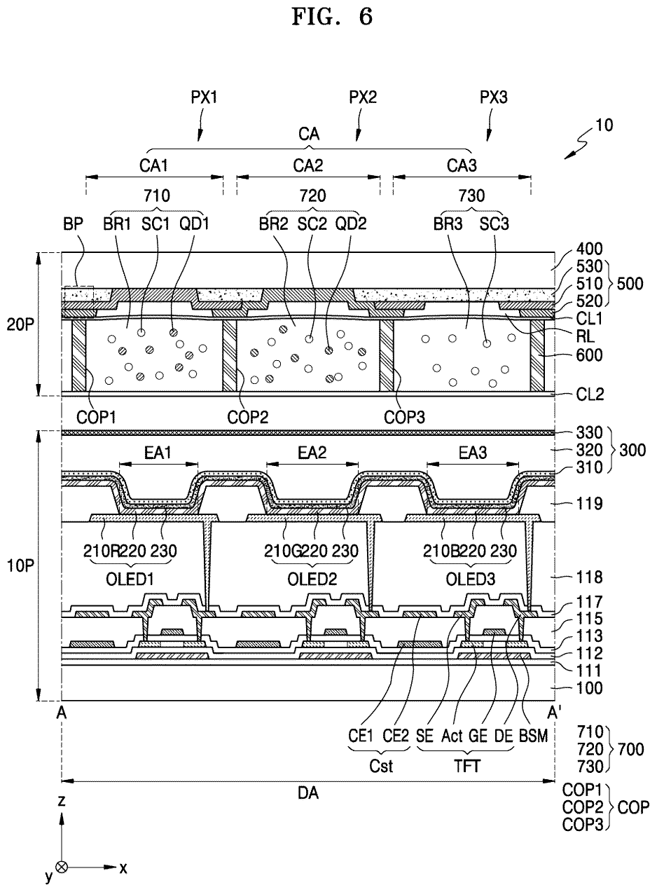

FIG. 6 is a cross-sectional view taken along the line A-A′ of the display panel of FIG. 5.

Referring to FIG. 6, the display panel 10 may include the first pixel PX1, the second pixel PX2, and the third pixel PX3 located in the display area DA. However, this is merely an example, and the display panel 10 may include more pixels. Although the first pixel PX1, the second pixel PX2, and the third pixel PX3 are adjacent to each other in FIG. 6, in one or more other embodiments, the first pixel PX1, the second pixel PX2, and the third pixel PX3 may not be adjacent to each other.

The first pixel PX1, the second pixel PX2, and the third pixel PX3 may emit different light. For example, the first pixel PX1 may emit red light, the second pixel PX2 may emit green light, and the third pixel PX3 may emit blue light.

In one or more embodiments, the display panel 10 may include the lower panel 10P and the upper panel 20P. The lower panel 10P may include the first substrate 100, and a light-emitting element located on the first substrate 100. The light-emitting element may include an emission layer 220. In one or more embodiments, the lower panel 10P may include the first organic light-emitting diode OLED1, the second organic light-emitting diode OLED2, and the third organic light-emitting diode OLED3 located on the first substrate 100. The first organic light-emitting diode OLED1, the second organic light-emitting diode OLED2, and the third organic light-emitting diode OLED3 may include the emission layer 220.

A stacked structure of the lower panel 10P will now be described in detail.

The first substrate 100 may include a glass material, a ceramic material, a metal material, or a flexible or bendable material. When the first substrate 100 is flexible or bendable, the first substrate 100 may include a polymer resin, such as a polyethersulfone, polyacrylate, polyetherimide, polyethylene naphthalate, polyethylene terephthalate, polyphenylene sulfide, polyarylate, polyimide, polycarbonate, or cellulose acetate propionate. The first substrate 100 may have a single or multi-layer structure including the above material, and when the first substrate 100 has a multi-layer structure, the first substrate 100 may further include an inorganic layer. In one or more embodiments, the first substrate 100 may have a structure including an organic material, an inorganic material, and an organic material.

In one or more embodiments, a barrier layer may be further provided between the first substrate 100 and a first buffer layer 111. The barrier layer may reduce, prevent, or minimize impurities from the first substrate 100, etc. from penetrating into a semiconductor layer Act. The barrier layer may include an inorganic material, such as oxide or nitride, an organic material, or a combination of an organic material and an inorganic material, and may have a single or multi-layer structure including an inorganic material and an organic material.

A bias electrode BSM may be located on the first buffer layer 111 to correspond to a thin-film transistor TFT (as used herein, “located on” may mean “above”). In one or more embodiments, a voltage may be applied to the bias electrode BSM. Also, the bias electrode BSM may reduce or prevent external light reaching the semiconductor layer Act. Accordingly, characteristics of the thin-film transistor TFT may be stabilized. The bias electrode BSM may be omitted when suitable.

The semiconductor layer Act may be located on a second buffer layer 112. The semiconductor layer Act may include amorphous silicon or polysilicon. In one or more other embodiments, the semiconductor layer Act may include an oxide of at least one material selected from the group consisting of indium (In), gallium (Ga), tin (Sn), zirconium (Zr), vanadium (V), hafnium (Hf), cadmium (Cd), germanium (Ge), chromium (Cr), titanium (Ti), aluminum (Al), cesium (Cs), cerium (Ce), or zinc (Zn). In some embodiments, the semiconductor layer Act may be formed of a Zn oxide-based material, such as Zn oxide, In—Zn oxide, or Ga—In—Zn oxide. In one or more other embodiments, the semiconductor layer Act may be formed of an In—Ga—Zn—O (IGZO), In—Sn—Zn—O (ITZO), or In—Ga—Sn—Zn—O (IGTZO) semiconductor containing a metal, such as indium (In), gallium (Ga), or tin (Sn) in ZnO. The semiconductor layer Act may include a channel region, and a source region and a drain region located on both sides of the channel region. The semiconductor layer Act may have a single or multi-layer structure.

A gate electrode GE may be located on the semiconductor layer Act with a gate-insulating layer 113 therebetween. The gate electrode GE may at least partially overlap the semiconductor layer Act. The gate electrode GE may include molybdenum (Mo), aluminum (Al), copper (Cu), or titanium (Ti), and may have a single or multi-layer structure. For example, the gate electrode GE may have a single-layer structure including Mo. A first electrode CE1 of the storage capacitor Cst may be located on the same layer as the gate electrode GE. The first electrode CE1 and the gate electrode GE may be formed of the same material.

Although the gate electrode GE of the thin-film transistor TFT and the first electrode CE1 of the storage capacitor Cst are separately located in FIG. 6, the storage capacitor Cst may overlap the thin-film transistor TFT. In this case, the gate electrode GE of the thin-film transistor TFT may function as the first electrode CE1 of the storage capacitor Cst.

An interlayer insulating layer 115 may be provided to cover the gate electrode GE and the first electrode CE1 of the storage capacitor Cst. The interlayer insulating layer 115 may include silicon oxide (SiO₂), silicon nitride (SiNX), silicon oxynitride (SiON), aluminum oxide (Al₂O₃), titanium oxide (TiO₂), tantalum oxide (Ta₂O₅), hafnium oxide (HfO₂), or zinc oxide (ZnO).

A second electrode CE2 of the storage capacitor Cst, a source electrode SE, and a drain electrode DE may be located on the interlayer insulating layer 115.

Each of the second electrode CE2 of the storage capacitor Cst, the source electrode SE, and the drain electrode DE may include a conductive material, such as Mo, Al, Cu, or Ti, and may have a single or multi-layer structure including the above material. For example, each of the second electrode CE2, the source electrode SE, and the drain electrode DE may have a multi-layer structure including Ti/Al/Ti. The source electrode SE and the drain electrode DE may be connected to the source region or the drain region of the semiconductor layer Act through a contact hole.

The second electrode CE2 and the first electrode CE1 of the storage capacitor Cst overlap each other with the interlayer insulating layer 115 therebetween to form the storage capacitor Cst. In this case, the interlayer insulating layer 115 may function as a dielectric layer of the storage capacitor Cst.

A wiring protection layer 117 may be located on the second electrode CE2 of the storage capacitor Cst, the source electrode SE, and the drain electrode DE. In this case, the wiring protection layer 117 may include an inorganic insulating material, such as silicon nitride, silicon oxide, and/or silicon oxynitride. The wiring protection layer 117 may reduce or prevent a wiring including a metal (e.g., copper), which may be damaged by an etchant during a process of manufacturing a display apparatus, from being exposed to an etching environment.

A planarization layer 118 may be located on the wiring protection layer 117. The planarization layer 118 may have a single or multi-layer structure formed of an organic material, and may provide a flat top surface. The planarization layer 118 may include benzocyclobutene (BCB), polyimide, hexamethyldisiloxane (HMDSO), a general-purpose polymer, such as polymethyl methacrylate (PMMA) or polystyrene (PS), a polymer derivative having a phenol-based group, an acrylic polymer, an imide-based polymer, an aryl ether-based polymer, an amide-based polymer, a fluorinated polymer, a p-xylene-based polymer, a vinyl alcohol-based polymer, or a blend thereof.

A display element may be located on the planarization layer 118. In one or more embodiments, the first organic light-emitting diode OLED1, the second organic light-emitting diode OLED2, and the third organic light-emitting diode OLED3 may be located on the planarization layer 118. The first organic light-emitting diode OLED1, the second organic light-emitting diode OLED2, and the third organic light-emitting diode OLED3 may respectively include a first pixel electrode 210R, a second pixel electrode 210G, and a third pixel electrode 210B. In one or more embodiments, the first organic light-emitting diode OLED1, the second organic light-emitting diode OLED2, and the third organic light-emitting diode OLED3 may commonly include the emission layer 220 and a counter electrode 230.

Each of the first pixel electrode 210R, the second pixel electrode 210G, and the third pixel electrode 210B may be a (semi)transmissive electrode or a reflective electrode. In some embodiments, each of the first pixel electrode 210R, the second pixel electrode 210G, and the third pixel electrode 210B may include a reflective layer formed of Ag, Mg, Al, Pt, Pd, Au, Ni, Nd, Ir, Cr, or a compound thereof and a transparent or semi-transparent electrode layer formed on the reflective layer. The transparent or semi-transparent electrode layer may include at least one selected from the group consisting of indium tin oxide (ITO), indium zinc oxide (IZO), zinc oxide (ZnO), indium oxide (In₂O₃), indium gallium oxide (IGO), or aluminum zinc oxide (AZO). In some embodiments, each of the first pixel electrode 210R, the second pixel electrode 210G, and the third pixel electrode 210B may be formed of ITO/Ag/ITO.

A pixel-defining film 119 may be located on the planarization layer 118. The pixel-defining film 119 may include openings through which central portions of the first pixel electrode 210R, the second pixel electrode 210G, and the third pixel electrode 210B are respectively exposed. The pixel-defining film 119 may cover edges of the first pixel electrode 210R, the second pixel electrode 210G, and the third pixel electrode 210B. The pixel-defining film 119 may increase a distance between an edge of each of the first pixel electrode 210R, the second pixel electrode 210G, and the third pixel electrode 210B and the counter electrode 230 on the first pixel electrode 210R, the second pixel electrode 210G, and the third pixel electrode 210B, to reduce or prevent the likelihood of an arc or the like from occurring at the edge of each of each of the first pixel electrode 210R, the second pixel electrode 210G, and the third pixel electrode 210B.

The pixel-defining film 119 may be formed of at least one organic insulating material selected from the group consisting of polyimide, polyamide, an acrylic resin, benzocyclobutene, or a phenolic resin by using spin coating or the like.

The emission layer 220 of the first organic light-emitting diode OLED1, the second organic light-emitting diode OLED2, and the third organic light-emitting diode OLED3 may include an organic material including a fluorescent or phosphorescent material that emits red light, green light, blue light, or white light. The emission layer 220 may be formed of a low molecular weight organic material or a high molecular weight organic material, and a functional layer, such as a hole transport layer (HTL), a hole injection layer (HIL), an electron transport layer (ETL), and an electron injection layer (EIL) may be selectively further located under or over the emission layer 220. Although the emission layer 220 is integrally formed over the first pixel electrode 210R, the second pixel electrode 210G, and the third pixel electrode 210B in FIG. 4, the present disclosure is not limited thereto, various modifications may be made, for example, the emission layer 220 being located to correspond to each of the first pixel electrode 210R, the second pixel electrode 210G, and the third pixel electrode 210B.

Although the emission layer 220 may include a layer that is integrally formed over the first pixel electrode 210R, the second pixel electrode 210G, and the third pixel electrode 210B as described above, the emission layer 220 may include a layer that is patterned to correspond to each of the first pixel electrode 210R, the second pixel electrode 210G, and the third pixel electrode 210B when suitable. In one or more embodiments, the emission layer 220 may be a first color emission layer. The first color emission layer may be integrally formed over the first pixel electrode 210R, the second pixel electrode 210G, and the third pixel electrode 210B, or may be patterned to correspond to each of the first pixel electrode 210R, the second pixel electrode 210G, and the third pixel electrode 210B when suitable. The first color emission layer may emit light of a first wavelength band, for example, light having a wavelength of about 450 nm to about 495 nm.

The counter electrode 230 may be located on the emission layer 220 to correspond to the first pixel electrode 210R, the second pixel electrode 210G, and the third pixel electrode 210B. The counter electrode 230 may be integrally formed in a plurality of organic light-emitting devices. In some embodiments, the counter electrode 230 may be a transparent or semi-transparent electrode, and may include a metal thin film having a low work function including lithium (Li), calcium (Ca), LiF/Ca, LiF/Al, aluminum (Al), silver (Ag), magnesium (Mg), or a compound thereof. Also, a transparent conductive oxide (TCO) film, such as ITO, IZO, ZnO, or In₂O₃ may be further located on the metal thin film.

In one or more embodiments, first light may be generated in a first emission area EA1 of the first organic light-emitting diode OLED1 and may be emitted to the outside. The first emission area EA1 may be defined as a portion of the first pixel electrode 210R exposed through the opening of the pixel-defining film 119. Second light may be generated in a second emission area EA2 of the second organic light-emitting diode OLED2 and may be emitted to the outside. The second emission area EA2 may be defined as a portion of the second pixel electrode 210G exposed through the opening of the pixel-defining film 119. Third light may be generated in a third emission area EA3 of the third organic light-emitting diode OLED3 and may be emitted to the outside. The third emission area EA3 may be defined as a portion of the third pixel electrode 210B exposed through the opening of the pixel-defining film 119.

The first emission area EA1, the second emission area EA2, and the third emission area EA3 may be spaced apart from each other. A portion of the display area DA other than the first emission area EA1, the second emission area EA2, and the third emission area EA3 may be a non-emission area. The first emission area EA1, the second emission area EA2, and the third emission area EA3 may be divided by the non-emission area. In a plan view, the first emission area EA1, the second emission area EA2, and the third emission area EA3 may be located in any of various arrangements, such as a stripe arrangement or a PENTILE™ arrangement (PENTILE™ being a registered trademark of Samsung Display Co., Ltd., Republic of Korea). In a plan view, each of a shape of the first emission area EA1, a shape of the second emission area EA2, and a shape of the third emission area EA3 may be any one of a polygonal shape, a circular shape, and an elliptical shape.

In one or more embodiments, a spacer for reducing or preventing mask damage may be further provided on the pixel-defining film 119. The spacer may be integrally formed with the pixel-defining film 119. For example, the spacer and the pixel-defining film 119 may be concurrently or substantially simultaneously formed in the same process using a halftone mask process.

Because the first organic light-emitting diode OLED1, the second organic light-emitting diode OLED2, and the third organic light-emitting diode OLED3 may be damaged by external moisture or oxygen, the first organic light-emitting diode OLED1, the second organic light-emitting diode OLED2, and the third organic light-emitting diode OLED3 may be covered and protected by an encapsulation layer 300. The encapsulation layer 300 may cover the display area DA, and may extend to the outside of the display area DA. The encapsulation layer 300 may include at least one organic encapsulation layer or at least one inorganic encapsulation layer. For example, the encapsulation layer 300 may include a first inorganic encapsulation layer 310, an organic encapsulation layer 320, and a second inorganic encapsulation layer 330.

Because the first inorganic encapsulation layer 310 is formed along a structure under the first inorganic encapsulation layer 310, a top surface of the first inorganic encapsulation layer 310 may not be flat (e.g., may be uneven). The organic encapsulation layer 320 may cover the first inorganic encapsulation layer 310, and unlike the first inorganic encapsulation layer 310, the organic encapsulation layer 320 may have a substantially flat top surface.

Each of the first inorganic encapsulation layer 310 and the second inorganic encapsulation layer 330 may include at least one inorganic material from among aluminum oxide (Al₂O₃), titanium oxide (TiO₂), tantalum oxide (Ta₂O₅), hafnium oxide (HfO₂), zinc oxide (ZnO), silicon oxide (SiO₂), silicon nitride (SiNX), or silicon oxynitride (SiON). The organic encapsulation layer 320 may include a polymer-based material. Examples of the polymer-based material may include an acrylic resin, an epoxy resin, polyimide, and polyethylene. In one or more embodiments, the organic encapsulation layer 320 may include acrylate.

Even if cracks occur in the encapsulation layer 300, the cracks may not be connected between, or may not be continuous between, the first inorganic encapsulation layer 310 and the organic encapsulation layer 320, or between the organic encapsulation layer 320 and the second inorganic encapsulation layer 330, due to the above multi-layer structure. Accordingly, the formation of a path through which external moisture or oxygen penetrates into the display area DA may be reduced, prevented, or minimized.

In one or more embodiments, other layers, such as a capping layer, may be located between the first inorganic encapsulation layer 310 and the counter electrode 230 when suitable.

The upper panel 20P may include the second substrate 400, a color filter layer 500, a refractive layer RL, a first capping layer CL1, a light conversion unit LC, and a second capping layer CL2. The second substrate 400 may be located on the first substrate 100 with a light-emitting element therebetween. The second substrate 400 may be located on the first organic light-emitting diode OLED1, the second organic light-emitting diode OLED2, and the third organic light-emitting diode OLED3.

The second substrate 400 may include a central area CA overlapping the display element. In one or more embodiments, the central area CA may include a first central area CA1, a second central area CA2, and a third central area CA3. The first central area CA1 may overlap the first organic light-emitting diode OLED1 and/or the first emission area EA1. The second central area CA2 may overlap the second organic light-emitting diode OLED2 and/or the second emission area EA2. The third central area CA3 may overlap the third organic light-emitting diode OLED3 and/or the third emission area EA3.

The second substrate 400 may include glass, a metal, or a polymer resin. When the second substrate 400 is flexible or bendable, the second substrate 400 may include a polymer resin, such as a polyethersulfone, polyacrylate, polyetherimide, polyethylene naphthalate, polyethylene terephthalate, polyphenylene sulfide, polyarylate, polyimide, polycarbonate, or cellulose acetate propionate. In one or more embodiments, the second substrate 400 may have a multi-layer structure including two layers each including such a polymer resin, and a barrier layer including an inorganic material, such as silicon oxide (SiO₂), silicon nitride (SiNX), or silicon oxynitride (SiON) located between the two layers.

The color filter layer 500 may be located on a bottom surface of the second substrate 400 facing the first substrate 100. The color filter layer 500 may include a first color filter 510, a second color filter 520, and a third color filter 530. The first color filter 510 may be located on the first central area CA1. The second color filter 520 may be located on the second central area CA2. The third color filter 530 may be located on the third central area CA3. Each of the first color filter 510, the second color filter 520, and the third color filter 530 may be formed of a photosensitive resin material. Each of the first color filter 510, the second color filter 520, and the third color filter 530 may include a dye producing a unique color. The first color filter 510 may transmit only light having a wavelength of about 630 nm to about 780 nm, the second color filter 520 may transmit only light having a wavelength of about 495 nm to about 570 nm, and the third color filter 530 may transmit only light having a wavelength of about 450 nm to about 495 nm.

The color filter layer 500 may reduce external light reflection from the display panel 10. For example, when external light reaches the first color filter 510, only light having the corresponding wavelength may pass through the first color filter 510 and light having other wavelengths may be absorbed by the first color filter 510. Accordingly, from among external light incident on the display panel 10, only light having the corresponding wavelength may pass through the first color filter 510, and part of the light may be reflected by the counter electrode 230 and/or the first pixel electrode 210R under the first color filter 510 and then may be emitted back to the outside. From among external light incident on a location where the first pixel PX1 is located, only part is reflected to the outside, and thus, external light reflection may be reduced. This description may apply to the second color filter 520 and the third color filter 530.

The first color filter 510, the second color filter 520, and the third color filter 530 may overlap each other. The first color filter 510, the second color filter 520, and the third color filter 530 may overlap each other between any one central area CA and another central area CA.

For example, the first color filter 510, the second color filter 520, and the third color filter 530 may overlap each other between the first central area CA1 and the second central area CA2. In this case, the third color filter 530 may be located between the first central area CA1 and the second central area CA2. The first color filter 510 may extend from the first central area CA1, and may overlap the third color filter 530. The second color filter 520 may extend from the second central area CA2, and may overlap the third color filter 530.

The first color filter 510, the second color filter 520, and the third color filter 530 may overlap each other between the second central area CA2 and the third central area CA3. The first color filter 510 may be located between the second central area CA2 and the third central area CA3. The second color filter 520 may extend from the second central area CA2, and may overlap the first color filter 510. The third color filter 530 may extend from the third central area CA3, and may overlap the first color filter 510.

The first color filter 510, the second color filter 520, and the third color filter 530 may overlap each other between the third central area CA3 and the first central area CA1. The second color filter 520 may be located between the third central area CA3 and the first central area CA1. The third color filter 530 may extend from the third central area CA3 and may overlap the second color filter 520. The first color filter 510 may extend from the first central area CA1 and may overlap the second color filter 520.

As described above, the first color filter 510, the second color filter 520, and the third color filter 530 may overlap each other to define a light-blocking portion BP. Accordingly, the color filter layer 500 may prevent or reduce color mixing, even without a separate light-blocking member.

The refractive layer RL may be located in the central area CA. The refractive layer RL may be located in the first central area CA1, the second central area CA2, and the third central area CA3. The refractive layer RL may include an organic material. In one or more embodiments, a refractive index of the refractive layer RL may be less than a refractive index of the first capping layer CL1. In one or more embodiments, a refractive index of the refractive layer RL may be less than a refractive index of the color filter layer 500. Accordingly, the refractive layer RL may concentrate light.

The first capping layer CL1 may be located on bottom surfaces of the refractive layer RL and the color filter layer 500. In one or more embodiments, the first capping layer CL1 may be located between the color filter layer 500 and the light conversion unit LC. The first capping layer CL1 may protect the refractive layer RL and the color filter layer 500. The first capping layer CL1 may prevent or reduce external impurities, such as moisture and/or air from penetrating and damaging or contaminating the refractive layer RL and/or the color filter layer 500. The first capping layer CL1 may include an inorganic material.

The light conversion unit LC may include a bank layer 600 and a functional layer 700. The bank layer 600 may be located on a bottom surface of the first capping layer CL1. The bank layer 600 may include an organic material. When suitable, the bank layer 600 may include a light-blocking material to function as a light-blocking layer. The light-blocking material may include at least one of, for example, a black pigment, a black dye, black particles, or metal particles.

A plurality of openings may be defined in the bank layer 600. For example, a central opening COP may be defined in the bank layer 600. The central opening COP may overlap the central area CA. In one or more embodiments, a plurality of central openings COP may overlap the central areas CA. For example, a first central opening COP1 may overlap the first central area CA1. A second central opening COP2 may overlap the second central area CA2. A third central opening COP3 may overlap the third central area CA3.

The functional layer 700 may fill the central opening COP. In one or more embodiments, the functional layer 700 may include at least one of quantum dots or a scatterer. In one or more embodiments, the functional layer 700 may include a first quantum dot layer 710, a second quantum dot layer 720, and a transmissive layer 730.

The first quantum dot layer 710 may overlap the first central area CA1. The first quantum dot layer 710 may fill the first central opening COP1. The first quantum dot layer 710 may overlap the first emission area EA1. The first pixel PX1 may include the first organic light-emitting diode OLED1 and the first quantum dot layer 710.

The first quantum dot layer 710 may convert light of a first wavelength band generated by the emission layer 220 on the first pixel electrode 210R into light of a second wavelength band. For example, when light having a wavelength ranging from about 450 nm to about 495 nm is generated by the emission layer 220 on the first pixel electrode 210R, the first quantum dot layer 710 may convert the light into light having a wavelength ranging from about 630 nm to about 780 nm. Accordingly, in the first pixel PX1, the light having a wavelength of about 630 nm to about 780 nm may be emitted to the outside through the second substrate 400. In one or more embodiments, the first quantum dot layer 710 may include first quantum dots QD1, a first scatterer SC1, and a first base resin BR1. The first quantum dots QD1 and the first scatterer SC1 may be dispersed in the first base resin BR1.

The second quantum dot layer 720 may overlap the second central area CA2. The second quantum dot layer 720 may fill the second central opening COP2. The second quantum dot layer 720 may overlap the second emission area EA2. The second pixel PX2 may include the second organic light-emitting diode OLED2 and the second quantum dot layer 720.

The second quantum dot layer 720 may convert light of the first wavelength band generated by the emission layer 220 on the second pixel electrode 210G into light of a third wavelength band. For example, when light having a wavelength ranging from about 450 nm to about 495 nm is generated by the emission layer 220 on the second pixel electrode 210G, the second quantum dot layer 720 may convert the light into light having a wavelength ranging from about 495 nm to about 570 nm. Accordingly, in the second pixel PX2, the light having a wavelength of about 495 nm to about 570 nm may be emitted to the outside through the second substrate 400. In one or more embodiments, the second quantum dot layer 720 may include second quantum dots QD2, a second scatterer SC2, and a second base resin BR2. The second quantum dots QD2 and the second scatterer SC2 may be dispersed in the second base resin BR2.

The transmissive layer 730 may overlap the third central area CA3. The transmissive layer 730 may fill the third central opening COP3. The transmissive layer 730 may overlap the third emission area EA3. The third pixel PX3 may include the third organic light-emitting diode OLED3 and the transmissive layer 730.

The transmissive layer 730 may emit light generated by the emission layer 220 on the third pixel electrode 210B to the outside without wavelength conversion. For example, when light having a wavelength of about 450 nm to about 495 nm is generated by the emission layer 220 on the third pixel electrode 210B, the transmissive layer 730 may emit the light to the outside without wavelength conversion. In one or more embodiments, the transmissive layer 730 may include a third scatterer SC3 and a third base resin BR3. The third scatterer SC3 may be dispersed in the third base resin BR3. In one or more embodiments, the transmissive layer 730 may not include quantum dots.

At least one of the first quantum dots QD1 or the second quantum dots QD2 may include a semiconductor material, such as cadmium sulfide (CdS), cadmium telluride (CdTe), zinc sulfide (ZnS), or indium phosphide (InP). Quantum dots may have a size of several nanometers, and a wavelength of light after conversion may vary according to the size of quantum dots.

In one or more embodiments, a core of a quantum dot may be selected from among a Group II-VI compound, a Group III-V compound, a Group IV-VI compound, a Group IV element, a Group IV compound, and/or a combination thereof.

The Group II-VI compound may be selected from among a binary compound selected from the group consisting of CdSe, CdTe, ZnS, ZnSe, ZnTe, ZnO, HgS, HgSe, HgTe, MgSe, MgS, and/or a mixture thereof; a ternary compound selected from the group consisting of AgInS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and/or a mixture thereof; and/or a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and/or a mixture thereof.

The Group III-V compound may be selected from among a binary compound selected from the group consisting of GaN, GaP, GaAs, GaSb, AlN, AlP, AlAs, AlSb, InN, InP, InAs, InSb, and/or a mixture thereof; a ternary compound selected from the group consisting of GaNP, GaNAs, GaNSb, GaPAs, GaPSb, AlNP, AlNAs, AlNSb, AlPAs, AlPSb, InGaP, InNP, InNAs, InNSb, InPAs, InPSb, GaAlNP, and/or a mixture thereof; and/or a quaternary compound selected from the group consisting of GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and/or a mixture thereof.

The Group IV-VI compound may be selected from among a binary compound selected from the group consisting of SnS, SnSe, SnTe, PbS, PbSe, PbTe, and/or a mixture thereof; a ternary compound selected from the group consisting of SnSeS, SnSeTe, SnSTe, PbSeS, PbSeTe, PbSTe, SnPbS, SnPbSe, SnPbTe, and/or a mixture thereof; and/or a quaternary compound selected from the group consisting of SnPbSSe, SnPbSeTe, SnPbSTe, and/or a mixture thereof. The Group IV element may be selected from the group consisting of silicon (Si), germanium (Ge), and/or a mixture thereof. The Group IV compound may be a binary compound selected from the group consisting of SiC, SiGe, and/or a mixture thereof.

In this case, the binary compound, the ternary compound, or the quaternary compound may exist in particles at a uniform concentration, or may exist in the same particle divided into two states where concentration distributions are partially different. Also, the quantum dot may have a core/shell structure in which one quantum dot surrounds another quantum dot. An interface between the core and the shell may have a concentration gradient in which a concentration of an element in the shell gradually decreases toward the center.

In some embodiments, the quantum dot may have a core-shell structure including a core including a nanocrystal and a shell surrounding the core. The shell of the quantum dot may function as a protective layer for maintaining semiconductor properties by reducing or preventing chemical denaturation of the core and/or a charging layer for giving electrophoretic properties to the quantum dot. The shell may have a single or multi-layer structure. An interface between the core and the shell may have a concentration gradient in which a concentration of an element in the shell gradually decreases toward the center. Examples of the shell of the quantum dot may include an oxide of a metal or a non-metal, a semiconductor compound, and a combination thereof.

Examples of the oxide of the metal or the non-metal may include, but are not limited to, a binary compound, such as SiO₂, Al₂O₃, TiO₂, ZnO, MnO, Mn₂O₃, Mn₃O₄, CuO, FeO, Fe₂O₃, Fe₃O₄, CoO, Co₃O₄, or NiO, and/or a ternary compound, such as MgAl₂O₄, CoFe₂O₄, NiFe₂O₄, or CoMn₂O₄.

Also, examples of the semiconductor compound may include, but are not limited to, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, and/or AlSb.

Also, a quantum dot has a shape that is generally used in the art and is not specifically limited, and more specifically, a quantum dot may have a spherical shape, a pyramidal shape, a multi-arm shape, a cubic nanoparticle shape, a nanotube shape, a nanowire shape, a nanofiber shape, or a nanoplate particle shape.

A color of light emitted from the quantum dot may be controlled according to a particle size, and thus, the quantum dot may have any of various emission colors, such as blue, red, or green.

The first scatterer SC1, the second scatterer SC2, and the third scatterer SC3 may scatter light so that more light is emitted. The first scatterer SC1, the second scatterer SC2, and the third scatterer SC3 may increase light emission efficiency. At least one of the first scatterer SC1, the second scatterer SC2, or the third scatterer SC3 may include a metal or a metal oxide for uniformly scattering light. For example, at least one of the first scatterer SC1, the second scatterer SC2, or the third scatterer SC3 may be at least one of TiO2, ZrO2, Al2O3, In2O3, ZnO, SnO2, Sb2O3, or ITO. Also, at least one of the first scatterer SC1, the second scatterer SC2, or the third scatterer SC3 may have a refractive index of about 1.5 or more. Accordingly, the light emission efficiency of the functional layer 700 may be improved. In some embodiments, at least one of the first scatterer SC1, the second scatterer SC2, or the third scatterer SC3 may be omitted.

Each of the first base resin BR1, the second base resin BR2, and the third base resin BR3 may be a light-transmitting material. For example, at least one of the first base resin BR1, the second base resin BR2, or the third base resin BR3 may include a polymer resin, such as acryl, benzocyclobutene (BCB), or hexamethyldisiloxane (HMDSO).

The second capping layer CL2 may be located on a bottom surface of the light conversion unit LC. That is, the second capping layer CL2 may be located on the bank layer 600 and the functional layer 700. The second capping layer CL2 may protect the bank layer 600 and the functional layer 700. The second capping layer CL2 may prevent or reduce external impurities, such as moisture and/or air from penetrating and damaging or contaminating the bank layer 600 and/or the functional layer 700. The second capping layer CL2 may include an inorganic material.

In the display panel 10 as described above, light of the second wavelength band may be emitted from the first pixel PX1 to the outside, light of the third wavelength band may be emitted from the second pixel PX2 to the outside, and light of the first wavelength band may be emitted from the third pixel PX3 to the outside. That is, the display panel 10 may display a full-color image.

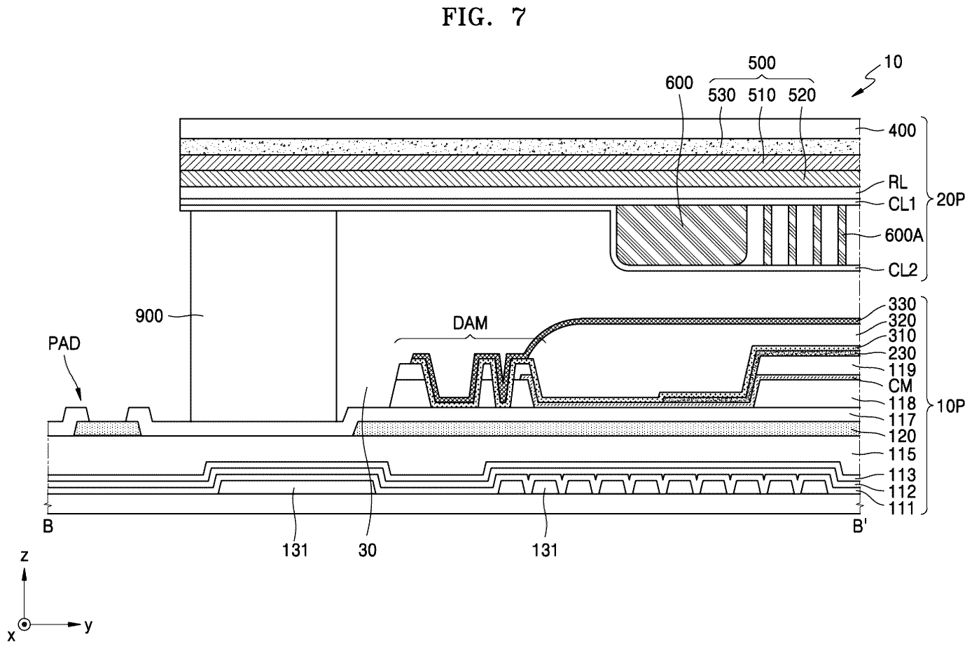

FIG. 7 is a cross-sectional view taken along the line B-B′ of the display panel of FIG. 5.

Referring to FIG. 7, the display panel 10 may include a dam unit DAM located at an edge of the first substrate 100. The dam unit DAM may be located on an outer perimeter of the display area DA to define a boundary of the organic encapsulation layer 320 when the organic encapsulation layer 320 is formed. In this case, at least one dam unit DAM may be provided. For example, a plurality of dam units DAM may be provided to be spaced apart from each other from an end of the first substrate 100.

The dam unit DAM may include an insulating layer. For example, the dam unit DAM may include the same layer as at least one of the planarization layer 118 or the pixel-defining film 119. Also, the dam unit DAM may include the wiring protection layer 117. In one or more other embodiments, the dam unit DAM may further include the same layer as a spacer located on the pixel-defining film 119. When the dam unit DAM includes a plurality of layers as described above, a height of one of the plurality of dam units DAM may be different from a height of another one of the plurality of dam units DAM. For example, among the plurality of dam units DAM, a height of the dam unit DAM closer to an end of the first substrate 100 may be greater than a height of another one of the plurality of dam units DAM.

A top surface of at least one of dams constituting the dam unit DAM may directly contact the first inorganic encapsulation layer 310 or the second inorganic encapsulation layer 330. In some embodiments, a top surface of at least one of the dams constituting the dam unit DAM in a plan view may not overlap the organic encapsulation layer 320. Also, the first inorganic encapsulation layer 310 and the second inorganic encapsulation layer 330 may directly contact each other on at least one of the dams constituting the dam unit DAM. That is, the first inorganic encapsulation layer 310 and the second inorganic encapsulation layer 330 may form an inorganic contact area, which may block or reduce penetration of moisture and impurities from the outside of the display panel 10 into light-emitting elements located in the display area DA (see FIG. 6).

The display panel 10 may include a plurality of signal wirings 131 located between the first substrate 100 and the first buffer layer 111. In this case, the plurality of signal wirings 131 may include a fan-out line. The plurality of signal wirings 131 may be located between the first buffer layer 111 and the second buffer layer 112 in addition to the above position. In one or more other embodiments, some of the plurality of signal wirings 131 may be located between the first buffer layer 111 and the first substrate 100, and others of the plurality of signal wirings 131 may be located between the first buffer layer 111 and the second buffer layer 112.

As described above, the display panel 10 may include the driving voltage input unit 120. The driving voltage input unit 120 may be located on the interlayer insulating layer 115. For example, the driving voltage input unit 120 may be located on the same layer as the source electrode SE (see FIG. 6) and/or the drain electrode DE (see FIG. 6) of the display area DA (see FIG. 6). In one or more embodiments, the common voltage input unit 110 (see FIG. 5) may be located on the same layer as the driving voltage input unit 120.

The driving voltage input unit 120 may extend outwardly in the non-display area NDA. The display panel 10 may include a connection wiring CM connected to the driving voltage input unit 120. In this case, the connection wiring CM may be connected to the driving voltage input unit 120, and an extension portion of the counter electrode 230 may be located on the connection wiring CM.

The display panel 10 may include the pad PAD. The pad PAD may include a pad electrode exposed to the outside. The pad PAD may be located outside the sealing member 900 in the display panel 10. An external flexible circuit board or the like may be connected to the pad PAD. Also, the pad PAD may be connected to the driving voltage input unit 120 and the plurality of signal wirings 131. In this case, the pad PAD may include a plurality of terminals.

The upper panel 20P may include the color filter layer 500 extending to the non-display area NDA. The color filter layer 500 may include the first color filter 510, the second color filter 520, and the third color filter 530 stacked in the non-display area NDA. Because the plurality of color filters (e.g., 510, 520, and 530) are stacked in an overlapping manner, light emitted from the lower panel 10P may not pass through the color filter layer 500. Accordingly, the non-display area NDA may be invisible.

The refractive layer RL may be located on the color filter layer 500, and at least one of the first capping layer CL1 or the second capping layer CL2 may be located on the refractive layer RL. That is, at least one of the first capping layer CL1 or the second capping layer CL2 may extend from a portion of the second substrate 400 corresponding to the display area DA (see FIG. 6) of the lower panel 10P to an end of the second substrate 400 to shield one surface of the refractive layer RL. At least one of the first capping layer CL1 or the second capping layer CL2 may include an inorganic insulating layer, such as silicon oxide (SiO2), silicon nitride (SiNX), and/or silicon oxynitride (SiON).

The bank layer 600 may be located between the first capping layer CL1 and the second capping layer CL2. The bank layer 600 may overlap a part of the non-display area NDA as well as the display area DA (see FIG. 6). The bank layer 600 may include a dummy bank layer 600A located in the non-display area NDA. In some embodiments, the dummy bank layer 600A may include additional openings not overlapping light-emitting elements in a plan view. The functional layer 700 (see FIG. 6) may be located in the plurality of openings of the dummy bank layer 600A. For example, the transmissive layer 730 (see FIG. 6) may be located in the plurality of openings of the dummy bank layer 600A.

The bank layer 600 may include a black matrix material, or a light-blocking material, such as a red pigment, a purple pigment, or a blue pigment. Alternatively, the bank layer 600 may include a metal oxide to increase a reflectance on a surface thereof, thereby effectively reducing, preventing, or minimizing external light incident on the second substrate 400 from reaching a driving circuit unit, etc.

The sealing member 900 may couple the first substrate 100 to the second substrate 400. In other words, the sealing member 900 may be located between the lower panel 10P and the upper panel 20P. The sealing member 900 may be located in the non-display area NDA to surround the outer perimeter of the display area DA. For example, the sealing member 900 may have a hollow quadrangular shape in a plan view. However, a shape of the sealing member 900 is not limited thereto. When each of the first substrate 100 and the second substrate 400 has any of various planar shapes, such as a triangular shape, a rhombus shape, a polygonal shape, a circular shape, or an elliptical shape, the sealing member 900 may have a planar shape, such as a hollow triangular shape, a hollow rhombus shape, a hollow polygonal shape, a hollow circular shape, or a hollow elliptical shape. In one or more embodiments, the sealing member 900 may be formed of an organic material. For example, the sealing member 900 may be formed of an epoxy resin. In one or more other embodiments, the sealing member 900 may be applied as a frit including glass or the like.

In some embodiments, a filling layer 30 including a filler may be located in a space between the lower panel 10P and the upper panel 20P surrounded by the sealing member 900. The filling layer 30 may fill the space between the lower panel 10P and the upper panel 20P. The filler included in the filling layer 30 may be formed of a material through which light may be transmitted. For example, the filler may be formed of a silicone-based organic material, an epoxy-based organic material, or an organic material including a mixture of a silicone-based organic material and an epoxy-based organic material.

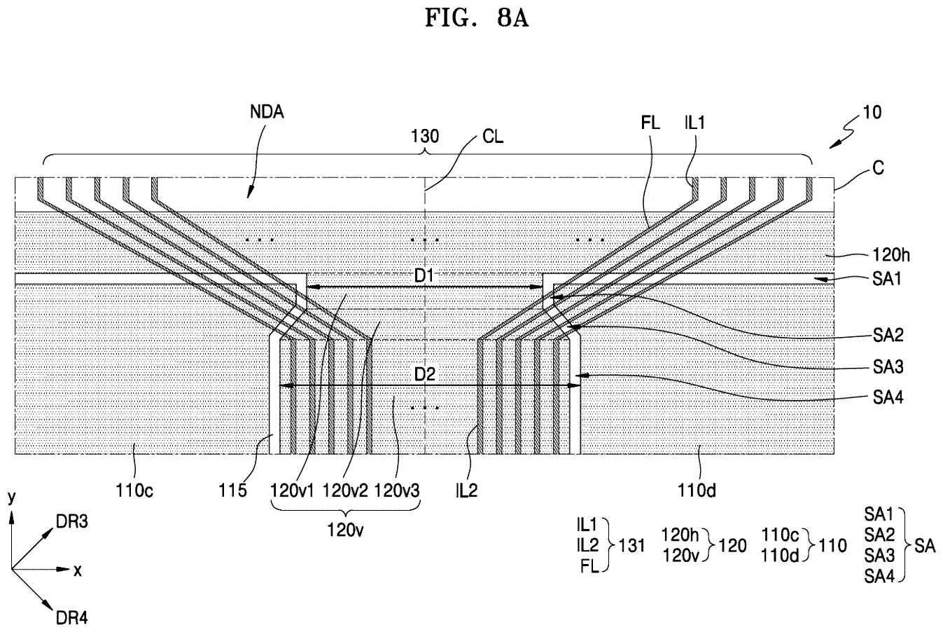

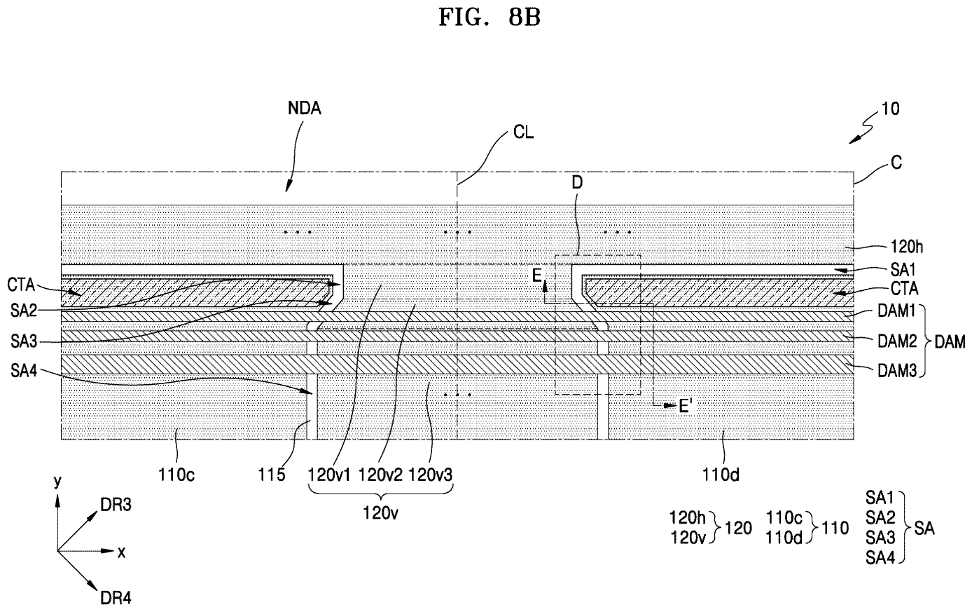

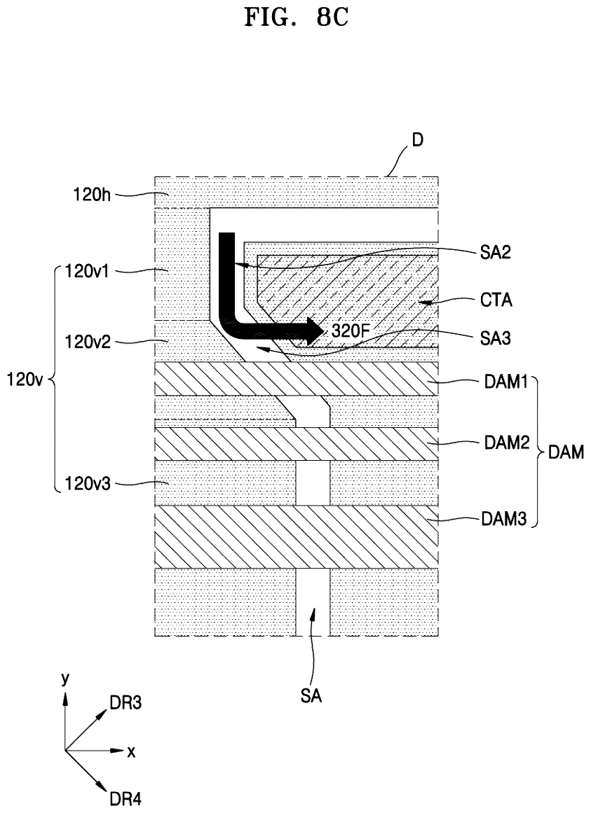

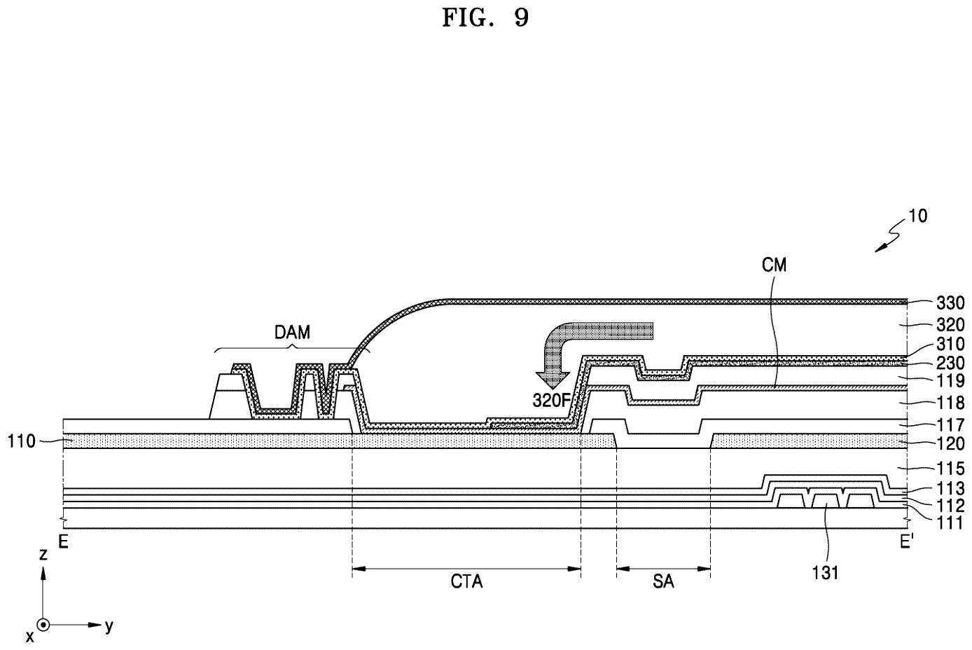

FIGS. 8A and 8B are plan views schematically illustrating a portion of a display panel, according to one or more embodiments of the present disclosure. FIG. 8C is an enlarged plan view schematically illustrating a portion D of the display panel of FIG. 8B. FIG. 9 is a cross-sectional view taken along the line E-E′ of the display panel of FIG. 8B. For convenience of explanation, in FIG. 8A, the driving voltage input unit 120, the common voltage input unit 110, and the plurality of signal wirings 131 are schematically illustrated, and other components may be omitted. Likewise, in FIG. 8B, for convenience of explanation, the driving voltage input unit 120, the common voltage input unit 110, and the dam units DAM are schematically illustrated, and other elements may be omitted.

First, referring to FIG. 8A, a signal wiring unit 130 may be located in the non-display area NDA. The signal wiring unit 130 may include the plurality of signal wirings 131 extending from the pad PAD (see FIG. 5) to be adjacent to the display area DA (see FIG. 5). The signal wirings 131 may be wirings for transmitting electrical signals to be applied to pixels located in the display area DA (see FIG. 5). Each of the plurality of signal wirings 131 may include a first input line IL1 adjacent to the display area DA (see FIG. 5), a second input line IL2 adjacent to the pad PAD (see FIG. 5), and a fan-out wiring FL electrically connecting the first input line IL1 to the second input line IL2. In one or more embodiments, the first input line IL1, the second input line IL2, and the fan-out wiring FL may be integrally formed with each other. In one or more other embodiments, at least one of the first input line IL1, the second input line IL2, or the fan-out wiring FL may be formed on a different respective layer, and may be electrically connected.

The second input lines IL2 are located adjacent to each other to be electrically connected to the pad PAD (see FIG. 5). The first input lines IL1 may be more spaced apart from each other, or may be spaced further apart from each other, than the second input lines IL2. This is due to positions of components that receive electrical signals transmitted from the plurality of signal wirings 131. Accordingly, as shown in FIG. 8A, an interval between the fan-out wirings FL may vary according to a position. For example, a distance between the fan-out wirings FL close to the first input line IL1 may be greater than a distance between the fan-out wirings FL close to the second input line IL2. This may be because the fan-out wirings FL extend in an oblique direction with respect to the second direction (e.g., the y direction). An angle formed between the fan-out wiring FL close to a virtual center line CL passing through the center of the fan-out wirings FL and the second direction (e.g., the y direction) may be less than an angle formed between the fan-out wiring FL that is located at an outermost position among the fan-out wirings FL and the second direction (e.g., the y direction).

Referring to FIG. 8A, the signal wiring unit 130 may partially overlap the common voltage input unit 110 and the driving voltage input unit 120 in a plan view.

The driving voltage input unit 120 may include a horizontal driving voltage input unit 120h extending in the first direction (e.g., the x direction), and a vertical driving voltage input unit 120v having the same center as the center of the virtual center line CL passing through the center of the fan-out wirings FL and extending in the second direction (e.g., the y direction). For example, the driving voltage input unit 120 may be arranged in a T shape that is symmetrical with respect to the virtual center line CL passing through the center of the fan-out wirings FL.

In one or more embodiments, the vertical driving voltage input unit 120v may include a first vertical driving voltage input unit 120v1, a second vertical driving voltage input unit 120v2, and a third vertical driving voltage input unit 120v3 sequentially located along the second direction (e.g., the y direction). The first vertical driving voltage input unit 120v1, the second vertical driving voltage input unit 120v2, and the third vertical driving voltage input unit 120v3 may be integrally formed with each other (e.g., may be integral, or formed as a single body). In other words, the first vertical driving voltage input unit 120v1 may be a portion extending outwardly from (e.g., from near) the horizontal driving voltage input unit 120h, the second vertical driving voltage input unit 120v2 may be a portion extending outwardly from the first vertical driving voltage input unit 120v1, and the third vertical driving voltage input unit 120v3 may be a portion extending outwardly from the second vertical driving voltage input unit 120v2.

In one or more embodiments, the first vertical driving voltage input unit 120v1 and the third vertical driving voltage input unit 120v3 may extend along the second direction (e.g., the y direction). That is, a side surface of each of the first vertical driving voltage input unit 120v1 and the third vertical driving voltage input unit 120v3 facing the common voltage input unit 110 may be parallel to the virtual center line CL. For example, each of the first vertical driving voltage input unit 120v1 and the third vertical driving voltage input unit 120v3 may have a rectangular shape in a plan view.

However, the first vertical driving voltage input unit 120v1 and the third vertical driving voltage input unit 120v3 may respectively have different widths in the first direction (e.g., the x direction). As shown in FIG. 8A, the first vertical driving voltage input unit 120v1 may have a first width D1 along the first direction (e.g., the x direction), and the third vertical driving voltage input unit 120v3 may have a second width D2 along the first direction (e.g., the x direction). In one or more embodiments, the second width D2 of the third vertical driving voltage input unit 120v3 may be greater than the first width D1 of the first vertical driving voltage input unit 120v1. However, the present disclosure is not limited thereto, and in one or more other embodiments, the first width D1 of the first vertical driving voltage input unit 120v1 may be greater than the second width D2 of the third vertical driving voltage input unit 120v3.

In one or more embodiments, the second vertical driving voltage input unit 120v2, which is located between the first vertical driving voltage input unit 120v1 and the third vertical driving voltage input unit 120v3, may be a portion extending (e.g., partially extending) in a diagonal direction between the first direction (e.g., the x direction) and the second direction (e.g., the y direction). In this case, the diagonal direction may refer to a third direction DR3 or a fourth direction DR4. That is, a side surface of the second vertical driving voltage input unit 120v2 facing the common voltage input unit 110 may extend in the diagonal direction. For example, the second vertical driving voltage input unit 120v2 may have a trapezoidal shape in a plan view.

That is, widths of an upper side and a lower side of the second vertical driving voltage input unit 120v2 may be different from each other. For example, one side of the second vertical driving voltage input unit 120v2 close to the first vertical driving voltage input unit 120v1 may have the same width as the first width D1, and the other side of the second vertical driving voltage input unit 120v2 close to the third vertical driving voltage input unit 120v3 may have the same width as the second width D2. In other words, the second vertical driving voltage input unit 120v2 may be a bridge portion connecting the first vertical driving voltage input unit 120v1 and the third vertical driving voltage input unit 120v3, which have different respective widths.

The third common voltage input unit 110c and the fourth common voltage input unit 110d may be spaced apart from each other with the driving voltage input unit 120 therebetween. In detail, the vertical driving voltage input unit 120v may be located between the third common voltage input unit 110c and the fourth common voltage input unit 110d. The third common voltage input unit 110c and the fourth common voltage input unit 110d may be symmetrical to each other with respect to the virtual center line CL passing through the center of the fan-out wirings FL.

In one or more embodiments, the common voltage input unit 110 may be spaced apart from the vertical driving voltage input unit 120v while maintaining a constant distance. Also, a width of a portion of the common voltage input unit 110 parallel to (e.g., adjacent to) the first vertical driving voltage input unit 120v1 along the first direction (e.g., the x direction) may be greater than a width of a portion of the common voltage input unit 110 parallel to (e.g., adjacent to) the third vertical driving voltage input unit 120v3 along the first direction (e.g., the x direction). Accordingly, a portion of a side surface of the common voltage input unit 110 facing the vertical driving voltage input unit 120v may extend in the diagonal direction that is between the first direction (e.g., the x direction) and the second direction (e.g., the y direction). That is, a portion of the common voltage input unit 110 parallel to (e.g., adjacent to) the second vertical driving voltage input unit 120v2 may have a shape whose width gradually decreases along the second direction (e.g., the y direction).

As the driving voltage input unit 120 and the common voltage input unit 110 are spaced apart from each other, a space between the driving voltage input unit 120 and the common voltage input unit 110 may be referred to as a separation area SA. As described above, the driving voltage input unit 120 and the common voltage input unit 110 may be located on/at the same layer, and the driving voltage input unit 120 and the common voltage input unit 110 may be located on/at the same layer as the source electrode SE (see FIG. 6) of the display area DA (see FIG. 6). That is, the driving voltage input unit 120 and the common voltage input unit 110 may be located on the interlayer insulating layer 115. Accordingly, the separation area SA may expose a top surface of the interlayer insulating layer 115 located under the driving voltage input unit 120 and the common voltage input unit 110.

In one or more embodiments, a portion of the separation area SA may extend in the diagonal direction between the first direction (e.g., the x direction) and the second direction (e.g., the y direction). In detail, the separation area SA may include a first separation area SA1 between the horizontal driving voltage input unit 120h and the common voltage input unit 110, a second separation area SA2 between the first vertical driving voltage input unit 120v1 and the common voltage input unit 110, a third separation area SA3 between the second vertical driving voltage input unit 120v2 and the common voltage input unit 110, and a fourth separation area SA4 between the third vertical driving voltage input unit 120v3 and the common voltage input unit 110. The first separation area SA1, the second separation area SA2, the third separation area SA3, and the fourth separation area SA4 are classified for convenience of explanation, and the first to fourth separation areas SA1, SA2, SA3, and SA4 may be integrally connected to each other.

Because the first separation area SA1 refers to an area between the horizontal driving voltage input unit 120h and the common voltage input unit 110, the first separation area SA1 may extend along the first direction (e.g., the x direction). Because the second separation area SA2 refers to an area between the first vertical driving voltage input unit 120v1 and the common voltage input unit 110, the second separation area SA2 may extend along the second direction (e.g., the y direction). Because the third separation area SA3 refers to an area between the second vertical driving voltage input unit 120v2 and the common voltage input unit 110, the third separation area SA3 may extend along the diagonal direction (e.g., DR3 or DR4). Because the fourth separation area SA4 refers to an area between the third vertical driving voltage input unit 120v3 and the common voltage input unit 110, the fourth separation area SA4 may extend along the second direction (e.g., the y direction).

Referring to FIG. 8B, the dam unit DAM may be located on the driving voltage input unit 120 and the common voltage input unit 110. The dam unit DAM may include a plurality of dams, and the dam unit DAM may surround the display area DA (see FIG. 5). In one or more embodiments, the dam unit DAM may include a first dam DAM1, a second dam DAM2, and a third dam DAM3. The first dam DAM1 may refer to a dam closest to the display area DA (see FIG. 5) in the dam unit DAM, and the third dam DAM3 may refer to a dam located at an outermost position in the dam unit DAM. The second dam DAM2 may refer to a dam located between the first dam DAM1 and the third dam DAM3 (e.g., between in plan view).

A portion of the dam unit DAM may overlap the driving voltage input unit 120 and the common voltage input unit 110 in a plan view. In detail, a portion of the dam unit DAM may overlap the vertical driving voltage input unit 120v and the common voltage input unit 110 in a plan view. In one or more embodiments, a portion of the first dam DAM1 in the dam unit DAM may overlap the second vertical driving voltage input unit 120v2 in a plan view. In other words, a portion of the first dam DAM1 may overlap the third separation area SA3 in a plan view. However, the present disclosure is not limited thereto, and in one or more other embodiments, the first dam DAM1 may extend across a boundary between the second vertical driving voltage input unit 120v2 and the third vertical driving voltage input unit 120v3.

The common voltage input unit 110 may further include a contact area CTA that may be electrically connected to the counter electrode 230 of the organic light-emitting diode OLED (see FIG. 6). In one or more embodiments, the contact area CTA may be located closer to the display area DA (see FIG. 5) than the dam unit DAM. The contact area CTA may be enlarged to be located close to the third separation area SA3 extending in the diagonal direction.

Referring to FIG. 9, a plurality of insulating layers located on the common voltage input unit 110 may not be located on the contact area CTA. In detail, the contact area CTA may be an area where a portion of the plurality of insulating layers overlapping the contact area CTA in a plan view is removed to expose a top surface of the common voltage input unit 110. For example, a portion of the wiring protection layer 117, the planarization layer 118, and the pixel-defining film 119 may be removed on the contact area CTA to expose a top surface of the common voltage input unit 110. Accordingly, the common voltage input unit 110 may directly contact the connection wiring CM in the contact area CTA to be electrically connected to an extension portion of the counter electrode 230.

Referring to FIGS. 8C and 9, the dam unit DAM may include a plurality of insulating layers. For example, each of a plurality of dams of the dam unit DAM may include the same layer as the planarization layer 118 and the pixel-defining film 119. In one or more other embodiments, the dam unit DAM may further include the wiring protection layer 117. The dam unit DAM may be located in the non-display area NDA to surround the display area DA (see FIG. 6) to reduce or prevent overflow of the organic encapsulation layer 320.

As described above, the driving voltage input unit 120 and the common voltage input unit 110 may be located on the same layer, and the separation area SA may be located between the driving voltage input unit 120 and the common voltage input unit 110. The separation area SA may be an area where no conductive layer is located on the same layer as the driving voltage input unit 120 and the common voltage input unit 110 so that a top surface of the interlayer insulating layer 115 is exposed. Accordingly, a portion of the dam unit DAM overlapping the separation area SA may have a height that is less than that of a portion of the dam unit DAM overlapping the driving voltage input unit 120 or the common voltage input unit 110.

Although a material of the organic encapsulation layer 320 is mainly applied to the display area DA (see FIG. 5), the material of the organic encapsulation layer 320 may flow outwardly even into the non-display area NDA. In this case, the first dam DAM1 may primarily block the flow of the organic encapsulation layer 320. However, because a portion of the first dam DAM1 overlapping the separation area SA has a height that is less than that of other portions, the organic encapsulation layer 320 may overflow beyond the first dam DAM1 through the area.

In this case, the display panel 10 according to one or more embodiments of the present disclosure may control a flow 320F of the organic encapsulation layer 320 through the separation area SA extending in the diagonal direction. In detail, because the material of the organic encapsulation layer 320 may flow outwardly from the display area DA (see FIG. 5), the material of the organic encapsulation layer 320 passing through the second separation area SA2 flows in the second direction (e.g., the y direction). In this case, when the third separation area SA3 is formed to extend in the diagonal direction (e.g., DR3 or DR4), the flow 320F of the organic encapsulation layer 320 may be changed to the diagonal direction.

Also, when the contact area CTA is located adjacent to the third separation area SA3 extending in the diagonal direction (e.g., DR3 or DR4) as described above, the material of the organic encapsulation layer 320 may be guided to flow from the third separation area SA3 to the contact area CTA. This is because the wiring protection layer 117, the planarization layer 118, and the pixel-defining film 119 are not located in the contact area CTA and thus, the contact area CTA has a relatively large step difference from surrounding portions. That is, the flow 320F of the organic encapsulation layer 320 may be controlled as marked by an arrow in FIGS. 8C and 9.

In conclusion, in the display panel 10 according to one or more embodiments of the present disclosure, because a portion of the driving voltage input unit 120 and the common voltage input unit 110 is formed in the diagonal direction, and because the contact area CTA is expanded to a position near the separation area SA, overflow of the organic encapsulation layer 320 may be prevented or reduced.

According to some embodiments of the present disclosure, a display panel and an electronic device for displaying a high-quality image may be provided. However, the aspects described above are examples, and the aspects of the present disclosure are not limited thereto.

While the present disclosure has been particularly shown and described with reference to embodiments thereof, it will be understood by one of ordinary skill in the art that various modifications and equivalent other embodiments made be made from the present disclosure. Accordingly, the true technical scope of the present disclosure is defined by the technical spirit of the appended claims, with functional equivalents thereof to be included therein.

What is claimed is:

1. A display panel comprising:
a substrate comprising a display area, and a non-display area outside the display area;
a driving voltage input unit in the non-display area, and comprising:
a horizontal driving voltage input unit extending along a first direction; and
a vertical driving voltage input unit extending along a second direction crossing the first direction, and comprising:
a first vertical driving voltage input unit having a side surface extending along the second direction;
a second vertical driving voltage input unit having a side surface extending along a diagonal direction between the first direction and the second direction; and
a third vertical driving voltage input unit having a side surface extending along the second direction, the first vertical driving voltage input unit, the second vertical driving voltage input unit, and third vertical driving voltage input unit being sequentially arranged along the second direction; and
a common voltage input unit in the non-display area, and spaced apart from the driving voltage input unit.

2. The display panel of claim 1, wherein the horizontal driving voltage input unit, the first vertical driving voltage input unit, the second vertical driving voltage input unit, and the third vertical driving voltage input unit are integral.

3. The display panel of claim 1, wherein the second vertical driving voltage input unit has a trapezoidal shape in a plan view.

4. The display panel of claim 1, wherein the first vertical driving voltage input unit has a first width along the first direction,
wherein the third vertical driving voltage input unit has a second width along the first direction that is different from the first width,
wherein one side of the second vertical driving voltage input unit adjacent the first vertical driving voltage input unit has the first width, and
wherein another side of the second vertical driving voltage input unit adjacent the third vertical driving voltage input unit has the second width.

5. The display panel of claim 1, wherein the common voltage input unit is provided as a plurality of common voltage input units, and
wherein the vertical driving voltage input unit is between adjacent ones of the common voltage input units adjacent along the first direction.

6. The display panel of claim 1, wherein the non-display area comprises a separation area where the driving voltage input unit and the common voltage input unit are spaced apart from each other, the separation area exposing a top surface of an insulating layer that is lower than the driving voltage input unit and the common voltage input unit, and having a portion extending in the diagonal direction.

7. The display panel of claim 1, wherein the non-display area comprises a separation area where the driving voltage input unit and the common voltage input unit are spaced apart from each other, the separation area exposing a top surface of an insulating layer that is lower than the driving voltage input unit and the common voltage input unit, and comprising:
a first separation area extending along the first direction between the horizontal driving voltage input unit and the common voltage input unit;
a second separation area extending along the second direction between the first vertical driving voltage input unit and the common voltage input unit;
a third separation area extending along the diagonal direction between the second vertical driving voltage input unit and the common voltage input unit; and
a fourth separation area extending along the second direction between the third vertical driving voltage input unit and the common voltage input unit.

8. The display panel of claim 1, further comprising dams in the non-display area and above the driving voltage input unit and the common voltage input unit,
wherein the dams are arranged to surround the display area, and
wherein the dams overlap the vertical driving voltage input unit and the common voltage input unit.

9. The display panel of claim 1, further comprising dams in the non-display area above the driving voltage input unit and the common voltage input unit and surrounding the display area in plan view,
wherein a closest one of the dams to the display area overlaps the second vertical driving voltage input unit.

10. The display panel of claim 1, further comprising:
dams in the non-display area above the driving voltage input unit and the common voltage input unit, and surrounding the display area in plan view;
insulating layers above the driving voltage input unit and the common voltage input unit; and
a light-emitting diode in the display area, and electrically connected to a contact area of the common voltage input unit at which a portion of the insulating layers is removed to expose a top surface of the common voltage input unit, the contact area being closer to the display area than the dams are.

11. The display panel of claim 1, further comprising:
dams in the non-display area above the driving voltage input unit and the common voltage input unit, and surrounding the display area in plan view;
a light-emitting diode in the display area; and
an encapsulation layer covering the light-emitting diode, and comprising a first inorganic encapsulation layer, an organic encapsulation layer above the first inorganic encapsulation layer, and a second inorganic encapsulation layer above the organic encapsulation layer and directly contacting the first inorganic encapsulation layer above the dams.

12. A display panel comprising:
a substrate comprising a display area, and a non-display area outside the display area;
a driving voltage input unit in the non-display area, and comprising a horizontal driving voltage input unit extending along a first direction, and a vertical driving voltage input unit extending along a second direction crossing the first direction; and
a common voltage input unit in the non-display area and spaced apart from the driving voltage input unit,
wherein the non-display area comprises a separation area where the driving voltage input unit and the common voltage input unit are spaced apart from each other, and having a portion extending in a diagonal direction between the first direction and the second direction.

13. The display panel of claim 12, wherein the separation area exposes a top surface of an insulating layer that is lower than the driving voltage input unit and the common voltage input unit.

14. The display panel of claim 12, wherein the common voltage input unit is in the non-display area, and is spaced apart from the driving voltage input unit,
wherein the vertical driving voltage input unit comprises:
a first vertical driving voltage input unit having a side surface facing the common voltage input unit and extending along the second direction;
a second vertical driving voltage input unit having a trapezoidal shape in a plan view, and having a side surface facing the common voltage input unit and extending along the diagonal direction; and
a third vertical driving voltage input unit having a side surface facing the common voltage input unit and extending along the second direction, the first vertical driving voltage input unit, the second vertical driving voltage input unit, and the third vertical driving voltage input unit being sequentially arranged along the second direction.

15. The display panel of claim 12, further comprising dams in the non-display area above the driving voltage input unit and the common voltage input unit, and surrounding the display area in plan view, and
wherein a closest one of the dams to the display area overlaps a portion of the separation area extending in the diagonal direction.

16. The display panel of claim 12, further comprising:
dams in the non-display area above the driving voltage input unit and the common voltage input unit, and surrounding the display area in plan view; and
a light-emitting diode in the display area, and electrically connected to a contact area of the common voltage input unit that is closer to the display area in plan view than the dams are.

17. An electronic device comprising:
a display panel; and
a lower cover as an exterior, and defining an opening exposing a part of the display panel,
wherein the display panel comprises:
a substrate comprising a display area, and a non-display area outside the display area;
a driving voltage input unit in the non-display area, and comprising a horizontal driving voltage input unit extending along a first direction, and a vertical driving voltage input unit extending along a second direction crossing the first direction, and comprising:
a first vertical driving voltage input unit having a side surface extending along the second direction;
a second vertical driving voltage input unit having a side surface extending along a diagonal direction between the first direction and the second direction; and
a third vertical driving voltage input unit having a side surface extending along the second direction, the first vertical driving voltage input unit, the second vertical driving voltage input unit, and third vertical driving voltage input unit being sequentially arranged along the second direction; and
a common voltage input unit in the non-display area and spaced apart from the driving voltage input unit.

18. The electronic device of claim 17, wherein the non-display area comprises a separation area where the driving voltage input unit and the common voltage input unit are spaced apart from each other that exposes a top surface of an insulating layer that is lower the driving voltage input unit and the common voltage input unit, and that has a portion extending in the diagonal direction.

19. The electronic device of claim 17, further comprising dams in the non-display area above the driving voltage input unit and the common voltage input unit, and surrounding the display area in plan view,
wherein a closest one of the dams to the display area overlaps the second vertical driving voltage input unit in a plan view.

20. The electronic device of claim 17, further comprising:
dams in the non-display area above the driving voltage input unit and the common voltage input unit, and surrounding the display area in plan view; and
a light-emitting diode in the display area, and electrically connected to a contact area of the common voltage input unit that is closer to the display area than the dams are.
